(19) United States
(12) Patent Application Publication
(10) Pub. No.: US 2026/0026153 A1
(43) Pub. Date: Jan. 22, 2026

(54) Display Device

(71) Applicant: LG Display Co., Ltd., Seoul (KR)

(72) Inventors: Sohee Kim, Seoul (KR); DongGeun Bae, Goyang-si (KR)

(21) Appl. No.: 19/219,892

(22) Filed: May 27, 2025

(30) Foreign Application Priority Data
Jul. 16, 2024 (KR) 10-2024-0093785

(51) Int. Cl. H10H 29/37; H10H 29/855

(52) U.S. Cl. CPC H10H 29/37; H10H 29/8552

(57) ABSTRACT

A display device comprises a sensor, a substrate on the sensor and having a display area comprising pixels, and a non-display area, a pixel drive circuits on the substrate, banks on the pixel drive circuits, a plurality of micro-LEDs on the banks and electrically connected to the drive circuits, and a black matrix on the plurality of micro-LEDs, wherein the pixels each comprise a first area that is non-overlapping with the plurality of micro-LEDs, and a second area excluding the first area, and wherein the black matrix in the first area comprises one or more first transmission holes. Accordingly, the black matrix, which is in an area that is non-overlapping with a micro-LED in each of a plurality of pixels, includes one or more transmission holes, such that a transmittance rate of a display panel may be increased.

### CROSS-REFERENCE TO RELATED APPLICATION

This application claims the priority of Republic of Korea Patent Application No. 10-2024-0093785 filed on Jul. 16, 2024, which is hereby incorporated by reference in its entirety.

### FIELD

The present disclosure relates to an apparatus and particularly to, for example, without limitation, a display device.

### DESCRIPTION OF THE RELATED ART

Display devices are being applied to various electronic devices such as televisions (TVs), mobile phones, notebook computers, and tablet computers.

As the display devices, there are an organic light-emitting display (OLED) configured to autonomously emit, and a liquid crystal display (LCD) that requires a separate light source.

Recently, a display device including a light-emitting diode (LED) has attracted attention as a next-generation display device. Because the light-emitting diode is made of an inorganic material instead of an organic material, the light-emitting diode may be quickly turned on or off, have excellent luminous efficiency, and display high-luminance images in comparison with the liquid crystal display device or the organic light-emitting display device.

### SUMMARY

An object to be achieved by the present disclosure is to provide a display device capable of suppressing the occurrence of a Mura on a display panel.

Another object to be achieved by the present disclosure is to provide a display device capable of improving a transmittance rate of a display panel.

Still another object to be achieved by the present disclosure is to provide a display device capable of improving detection abilities of sensors disposed in the display device.

Yet another object to be achieved by the present disclosure is to provide a display device capable of adjusting luminance of a display panel in accordance with an external environment.

Still yet another object to be achieved by the present disclosure is to provide a display device capable of operating a high-efficiency display device with low power consumption.

Objects of the present disclosure are not limited to the aforementioned objects, and other objects, which are not mentioned above, may be clearly understood by those skilled in the art from the following descriptions.

A display device according to an embodiment of the present disclosure comprises a sensor, a substrate disposed on the sensor and having a display area comprising a plurality of pixels, and a non-display area, a plurality of pixel drive circuits disposed on the substrate, a plurality of banks disposed on the plurality of pixel drive circuits, a plurality of micro-LEDs disposed on the plurality of banks and electrically connected to the plurality of pixel drive circuits, and a black matrix disposed on the plurality of micro-LEDs, wherein the plurality of pixels each comprise a first area that does not overlap the plurality of micro-LEDs, and a second area excluding the first area, and wherein the black matrix in the first area comprises one or more first transmission holes.

A display device according to an another embodiment of the present disclosure comprises a sensor, a substrate disposed on the sensor and having a display area comprising a plurality of pixels, and a non-display area, a plurality of pixel drive circuits disposed on the substrate, a plurality of banks disposed on the plurality of pixel drive circuits, a plurality of micro-LEDs disposed on the plurality of banks and electrically connected to the plurality of pixel drive circuits, and a black matrix disposed on the plurality of micro-LEDs, wherein the black matrix comprises: one or more first transmission holes that do not overlap the plurality of micro-LEDs in each of the plurality of pixels, and a plurality of second transmission holes that overlap at least some of the plurality of micro-LEDs.

According to the display device according to the present disclosure, the black matrix, which is disposed in the area that does not overlap the micro-LED in each of the plurality of pixels, includes one or more transmission holes, such that the transmittance rate of the display panel may be increased.

In addition, according to the display device according to the present disclosure, the black matrix including one or more transmission holes is disposed in the entire display area, which may inhibit or reduce a Mura from being visually recognized.

In addition, according to the display device according to the present disclosure, a change in external environment may be detected by the sensor disposed in the display device.

In addition, the display device according to the present disclosure may adjust the luminance of the display panel in accordance with the change in external environment.

In addition, the display device according to the present disclosure may adjust the luminance of the display panel in accordance with the external environment, thereby operating the high-efficiency display device with low power consumption.

The effects according to the present disclosure are not limited to the contents exemplified above, and more various effects are included in the present disclosure.

It is to be understood that both the foregoing general description and the following detailed description are exemplary and explanatory and are intended to provide further explanation of the inventive concepts as claimed.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exploded perspective view of a display device according to an embodiment of the present disclosure;

FIG. 2A is a top plan view of one surface of the display device according to an embodiment of the present disclosure;

FIG. 2B is a top plan view of a rear surface the display device according to an embodiment of the present disclosure;

FIG. 3 is an enlarged view of the display device according to an embodiment of the present disclosure;

FIG. 4 is a view illustrating a circuit structure of the display device according to an embodiment of the present disclosure;

FIG. 5 is a top plan view of the display device according to an embodiment of the present disclosure;

FIG. 6 is a top plan view of the display device according to an embodiment of the present disclosure;

FIG. 7 is a top plan view of the display device according to an embodiment of the present disclosure;

FIG. 8 is a top plan view of the display device according to an embodiment of the present disclosure;

FIG. 9 is a cross-sectional view taken along line IX-IX′ in FIG. 3 according to an embodiment of the present disclosure;

FIG. 10 is a cross-sectional view taken along line X-X′ in FIG. 8 according to an embodiment of the present disclosure;

FIG. 11 is a cross-sectional view of the display device according to an embodiment of the present disclosure;

FIG. 12 is a top plan view of a display device according to another embodiment of the present disclosure;

FIG. 13 is a top plan view of a display device according to still another embodiment of the present disclosure;

FIG. 14 is a top plan view of a display device according to yet another embodiment of the present disclosure;

FIG. 15 is a top plan view of a display device according to still yet another embodiment of the present disclosure;

FIG. 16 is a top plan view of a display device according to a further embodiment of the present disclosure; and

FIGS. 17 to 20 are views illustrating devices to which the display device according to the embodiments of the present disclosure are applied.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When explaining temporal relationships, terms such as “after,” “following,” “subsequent to,” or “before,” etc., may include non-consecutive cases unless terms like “immediately” or “directly” are used.

Terms such as “first,” “second,” etc. are used to describe various components, but these components are not limited by these terms. These terms are merely used to distinguish one component from another. Therefore, a first component mentioned herein could be a second component within the technical scope of the present disclosure.

In describing the components of the present disclosure, terms such as first, second, A, B, (a), or (b) may be used. These terms are only intended to distinguish that one component from other components, and the nature, order, sequence, or number of the respective component is not limited by these terms.

When a component is described as being “connected,” “coupled,” “joined,” or “attached” to another component, it should be understood that the component may be directly connected, coupled, joined, or attached to the other component, but unless explicitly specified otherwise, it may also be indirectly connected, coupled, joined, or attached with another component intervening between each component.

When a component or layer is described as being “in contact with” or “overlapping” another component or layer, the component or layer may directly contact or overlap the other component or layer, but unless explicitly specified otherwise, it should be understood that it may also indirectly contact or overlap with another component intervening between each component.

The term “at least one” should be understood to include all combinations of one or more of the associated components. For example, “at least one of first, second, and third components” means not only the first, second, or third component, but also includes all combinations of two or more components from among the first, second, and third components.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The terms “first direction”, “second direction”, “third direction”, “X-axis direction”, “Y-axis direction”, and “Z-axis direction” should not be interpreted solely as geometric relationships perpendicular to each other, but may indicate broader directionality within the range where the configuration of the present disclosure can function.

The features of various embodiments in the present disclosure may be partially or wholly combined or associated with each other, various technical interlocking and operations are possible, and each embodiment may be implemented independently of each other or may be implemented together in an associated relationship.

Any implementation described herein as an “example” is not necessarily to be construed as preferred or advantageous over other implementations.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure.

Hereinafter, a display device according to exemplary embodiments of the present disclosure will be described in detail with reference to accompanying drawings.

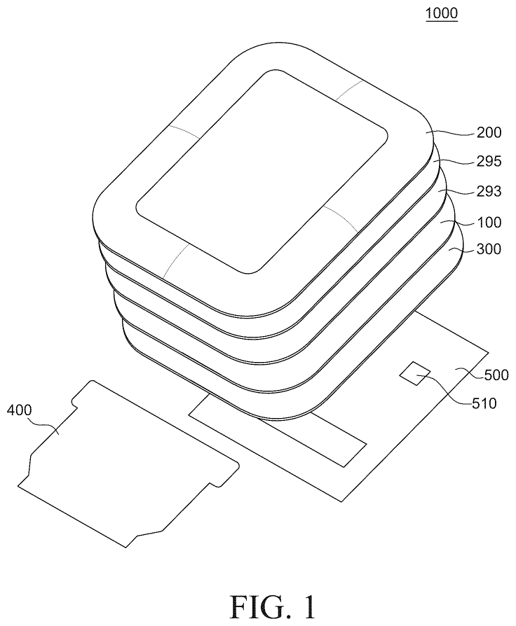

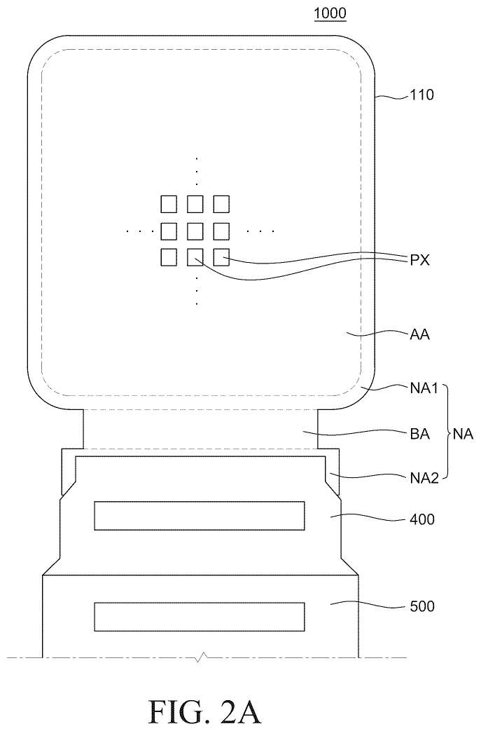

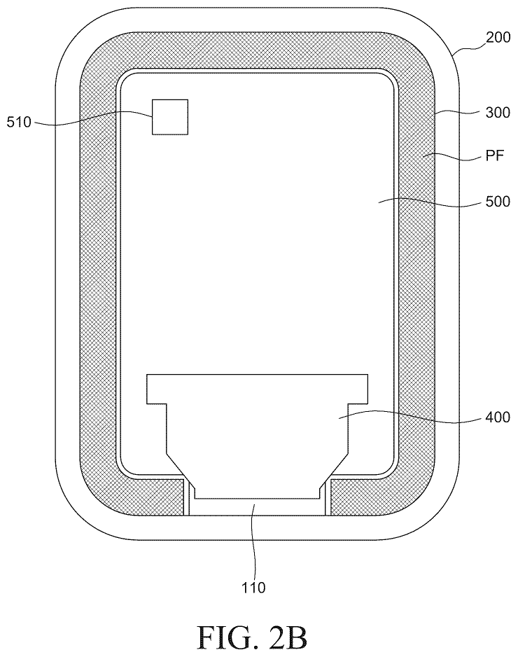

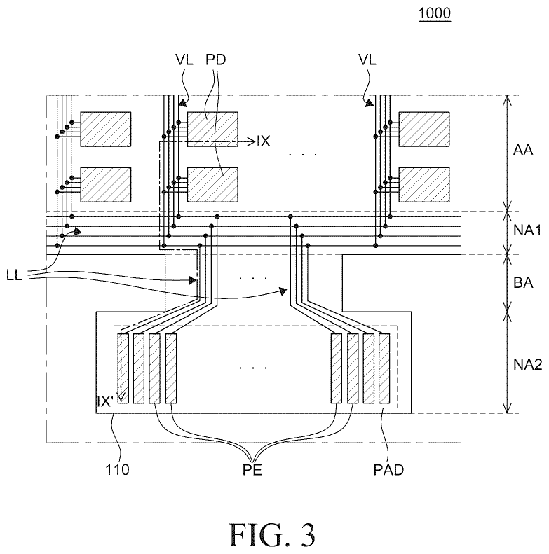

FIG. 1 is a perspective view illustrating a display device according to an embodiment of the present disclosure. FIG. 2A is a top plan view of one surface of the display device according to an embodiment of the present disclosure. FIG. 2B is a top plan view of a rear surface the display device according to an embodiment of the present disclosure. FIG. 3 is an enlarged view of the display device according to an embodiment of the present disclosure.

With reference to FIGS. 1 to 3, a display device 1000 according to an embodiment of the present disclosure may include a display panel 100, a polarizing layer 293, a bonding layer 295, a cover member 200, a support substrate 300, a flexible circuit board 400, and a printed circuit board 500.

For example, the display panel 100 of the display device 1000 may include a substrate 110. The substrate 110 may be a member configured to support other constituent elements of the display device 1000. The substrate 110 may be made of an insulating material. For example, the substrate 110 may be made of glass, resin, or the like. In addition, the substrate 110 may be made of a material having flexibility. For example, the substrate 110 may be made of a plastic material, such as polyimide (PI), having flexibility. However, the embodiments of the present disclosure are not limited thereto.

The display panel 100 may implement information, videos, and/or images to be provided to a user. For example, the display panel 100 may include a display area AA and a non-display area NA. For example, the substrate 110 may include the display area AA and the non-display area NA. The display area AA and the non-display area NA may not be described as being limited to the substrate 110, but the display area AA and the non-display area NA may be described for the entire display device 1000.

The display area AA may be an area in which images are displayed. The display area AA may include a plurality of pixels PX. The plurality of pixels PX may each include a plurality of subpixels. A plurality of micro-LEDs may be respectively disposed in the plurality of subpixels. Therefore, the display device 1000 according to the embodiment of the present disclosure may be an inorganic light-emitting display device.

The non-display area NA may be an area in which no image is displayed. Various lines and circuits for operating the plurality of pixels PX in the display area AA may be disposed in the non-display area NA. For example, various types of lines and drive circuits may be mounted in the non-display area NA, and a pad part PAD, to which an integrated circuit, a printed circuit, and the like are connected, may be disposed. However, the embodiments of the present disclosure are not limited thereto.

For example, the drive circuits may be a data drive circuit and/or a gate drive circuit. However, the embodiments of the present disclosure are not limited thereto. Lines for supplying control signals for controlling the drive circuits may be disposed. For example, the control signals may include various types of timing signals including clock signals, input data enable signals, and synchronizing signals. However, the embodiments of the present disclosure are not limited thereto. The control signal may be received through the pad part PAD. For example, link lines LL for transmitting signals may be disposed in the non-display area NA. For example, drive components, such as the flexible circuit board 400 and the printed circuit board 500, may be connected to the pad part PAD.

According to the present disclosure, the non-display area NA may include a first non-display area NA1, a bending area BA, and a second non-display area NA2. For example, the first non-display area NA1 may be an area that surrounds at least a part of the display area AA. The bending area BA may be a bendable area extending from at least any one of a plurality of sides of the first non-display area NA1. The second non-display area NA2 may be an area extending from the bending area BA, and the pad part PAD may be disposed in the second non-display area NA2. For example, the bending area BA may be in a curved state, and the remaining area of the substrate 110, except for the bending area BA, may be in a flat state. In this case, as the bending area BA is curved, the second non-display area NA2 may be positioned on a rear surface of the display area AA. However, the embodiments of the present disclosure are not limited thereto.

The display area AA of the substrate 110 or the display device 1000 may have various shapes in accordance with the design of the display device 1000. For example, the display area AA may have a rectangular shape having four corners with round shapes. However, the embodiments of the present disclosure are not limited thereto. In another example, the display area AA may have a circular shape or a rectangular shape having four corners with right-angled shapes. However, the embodiments of the present disclosure are not limited thereto.

According to the present disclosure, a width of the second non-display area NA2 in which a plurality of pad electrodes PE are disposed may be larger than a width of the bending area BA in which the plurality of link lines LL are disposed. In addition, a width of the display area AA in which the plurality of subpixels are disposed may be larger than a width of the bending area BA in which the plurality of link lines LL are disposed. The drawing illustrates that the width of the bending area BA may be smaller than a width of another area of the substrate 110. However, the shape of the substrate 110 including the bending area BA is illustrative, and the embodiments of the present disclosure are not limited thereto.

With reference to FIG. 3, a plurality of pixel drive circuits PD may be disposed in the display area AA. The plurality of pixel drive circuits PD may be circuits for operating the micro-LEDs of the plurality of subpixels. The plurality of pixel drive circuits PD may each include a plurality of transistors including a driving transistor, and a plurality of storage capacitors. The plurality of pixel drive circuits PD may control light-emitting operations of the plurality of micro-LEDs by supplying control signals, power, and drive currents to the micro-LEDs of the plurality of subpixels. For example, the pixel drive circuit PD may include a power line, and a signal line for controlling light-emitting on/off operations and/or light emission time of the micro-LED. For example, the plurality of pixel drive circuits PD may be operation drivers manufactured on a semiconductor substrate by using a metal-oxide-silicon field effect transistor (MOSFET) manufacturing process. However, the embodiments of the present disclosure are not limited thereto. The operation driver may include the plurality of pixel drive circuits PD and operate the plurality of subpixels.

With reference to FIG. 1 together, the flexible circuit board 400 and the printed circuit board 500 may be disposed below the display panel 100. The flexible circuit board 400 and the printed circuit board 500 may be disposed at least at one side edge of the display panel 100. However, the embodiments of the present disclosure are not limited thereto. One side of the flexible circuit board 400 may be attached to the display panel 100, and the other side of the flexible circuit board 400 may be attached to the printed circuit board 500. However, the embodiments of the present disclosure are not limited thereto. The flexible circuit board 400 may be a flexible film. However, the embodiments of the present disclosure are not limited thereto.

The pad part PAD including the plurality of pad electrodes PE may be disposed in the second non-display area NA2. The drive components including one or more flexible circuit boards (or flexible films) 400 and the printed circuit board 500 may be attached or bonded to the pad part PAD. The plurality of pad electrodes PE of the pad part PAD may be electrically connected to one or more flexible circuit boards (or flexible films) 400 and transmit various types of signals (or power) to the plurality of pixel drive circuits PD in the display area AA from the printed circuit board 500 and the flexible circuit board (or flexible film) 400.

The flexible circuit board (or flexible film) 400 may be a film having various types of components disposed on a base film having flexibility. For example, a drive integrated circuit (IC), such as a gate driver IC or a data driver IC, may be disposed on the flexible circuit board (or flexible film) 400. However, the embodiments of the present disclosure are not limited thereto. The drive IC may be a component configured to process data and driving signals for displaying images. The drive IC may be disposed in ways such as a chip-on-glass (COG) method, a chip-on-film (COF) method, or a tape carrier package (TCP) method depending on how the drive IC is mounted. However, the embodiments of the present disclosure are not limited thereto. The flexible circuit board (or flexible film) 400 may be attached or bonded to the plurality of pad electrodes PE by means of a conductive bonding layer. However, the embodiments of the present disclosure are not limited thereto.

The printed circuit board 500 may be a component electrically connected to one or more flexible circuit boards (or flexible films) 400 and configured to supply a signal to the drive IC. The printed circuit board 500 may be disposed at one side of the flexible circuit board (or flexible film) 400 and electrically connected to the flexible circuit board (or flexible film) 400. Various types of components for supplying various signals to the drive IC may be disposed on the printed circuit board 500. For example, various components, such as a timing controller, a power source, a memory, or a processor, may be disposed on the printed circuit board 500. For example, the printed circuit board 500 may include a power management integrated circuit (PMIC). However, the embodiments of the present disclosure are not limited thereto.

The printed circuit board 500 may include at least one hole 510. For example, the hole 510 may be a transmission hole. However, the embodiments of the present disclosure are not limited thereto.

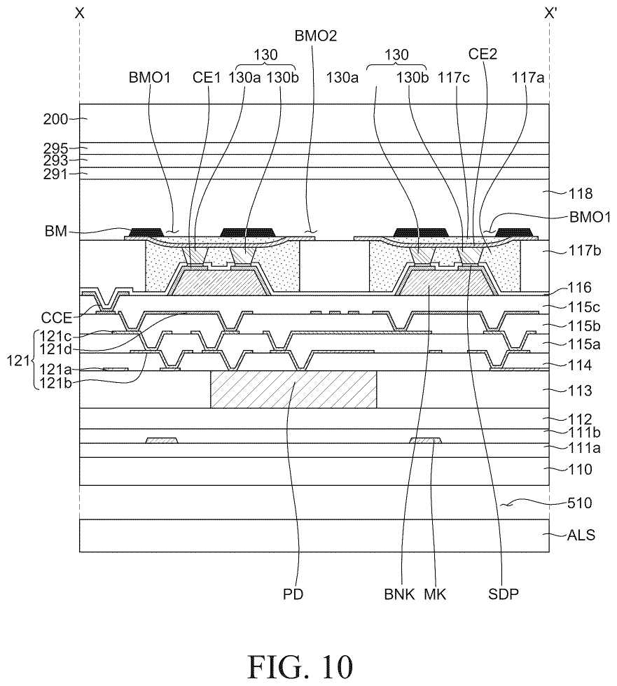

One or more sensors are disposed in an area corresponding to at least one hole 510. One or more sensors may be sensors that detect ambient light, temperature, and the like. For example, one or more sensors may include a light detection sensor, a temperature sensor, or the like. One or more sensors will be described below in detail with reference to FIG. 10.

With reference to FIG. 1, the polarizing layer 293 may be disposed on the display panel 100. The polarizing layer 293 may suppress or reduce a situation in which light generated from the external light source is introduced into the display panel 100 and affects the micro-LED or the like.

The cover member 200 may be disposed on the polarizing layer 293. The cover member 200 may be a member for protecting the display panel 100. The bonding layer 295 may be disposed between the polarizing layer 293 and the cover member 200. The cover member 200 may be attached to the display panel 100 by using the bonding layer 295. The bonding layer 295 may include an optically clear adhesive (OCA), an optically clear resin (OCR), a pressure-sensitive adhesive (PSA), or the like. However, the embodiments of the present disclosure are not limited thereto.

The support substrate 300 may be disposed between the display panel 100 and the printed circuit board 500. The support substrate 300 may reinforce the rigidity of the display panel 100. The support substrate 300 may be a backplate. However, the embodiments of the present disclosure are not limited thereto.

With reference to FIG. 2B, a black layer PF may be disposed and have a predetermined width along an edge area of a bottom surface of the support substrate 300. The black layer PF may be a light-blocking layer. For example, the black layer PF may be a black ink layer. For example, ink, which contains a black material capable of blocking light, is directly applied onto a bottom surface of the support substrate 300 by a silk screen printing process so as to have a predetermined width and thickness, such that the black layer PF may be disposed at a predetermined position on the bottom surface of the support substrate 300. However, the embodiments of the present disclosure are not limited thereto. An ink material of the black layer PF may not be decomposed under a particular environmental condition (e.g., a high-temperature, high-humidity environment). However, the embodiments of the present disclosure are not limited thereto.

With reference to FIGS. 1 to 3, the plurality of link lines LL may be disposed in the non-display area NA. The plurality of link lines LL may be lines configured to transmit various types of signals to the display area AA from one or more flexible circuit boards (or flexible films) 400 and the printed circuit board 500. The plurality of link lines LL may extend from the plurality of pad electrodes PE of the second non-display area NA2 toward the bending area BA and the first non-display area NA1 and be electrically connected to a plurality of drive lines VL in the display area AA. The plurality of pixel drive circuits PD may operate by receiving signals from one or more flexible circuit boards (or flexible films) 400 and the printed circuit board 500 through the drive lines VL in the display area AA and the link lines LL in the non-display area NA.

For example, the plurality of drive lines VL may be lines configured to transmit signals, which are outputted from the flexible circuit board (or flexible film) 400 and the printed circuit board 500, to the plurality of pixel drive circuits PD together with the plurality of link lines LL. The plurality of drive lines VL may be disposed in the display area AA and respectively electrically connected to the plurality of pixel drive circuits PD. The plurality of drive lines VL may extend from the display area AA toward the non-display area NA and be electrically connected to the plurality of link lines LL. Therefore, the signals outputted from the flexible circuit board (or flexible film) 400 and the printed circuit board 500 may be transmitted to the plurality of pixel drive circuits PD through the plurality of link lines LL and the plurality of drive lines VL.

When the bending area BA is bent, the plurality of link lines LL may also be partially bent. Stress may be concentrated on a part of the bent link line LL, and therefore, the link line LL may crack. Therefore, the plurality of link lines LL may be made of an electrically conductive material that is excellent in flexibility in order to reduce the occurrence of a crack when the bending area BA is bent. For example, the plurality of link lines LL may be made of an electrically conductive material, such as gold (Au), silver (Ag), or aluminum (Al), that is excellent in flexibility. However, the embodiments of the present disclosure are not limited thereto. In addition, the plurality of link lines LL may be made of one of various electrically conductive materials used for the display area AA. For example, the plurality of link lines LL may be made of molybdenum (Mo), chromium (Cr), titanium (Ti), nickel (Ni), neodymium (Nd), copper (Cu), and an alloy of silver (Ag) and magnesium (Mg), or an alloy thereof. However, the embodiments of the present disclosure are not limited thereto. The plurality of link lines LL may have a multilayer structure including various electrically conductive material. For example, the plurality of link lines LL may have a triple layer structure made of titanium (Ti), aluminum (Al), and titanium (Ti). However, the embodiments of the present disclosure are not limited thereto.

The plurality of link lines LL may have various shapes to reduce stress. At least a part of each of the plurality of link lines LL disposed in the bending area BA may extend in a direction identical to an extension direction of the bending area BA or extend in a direction different from the extension direction of the bending area BA to reduce stress. For example, in case that the bending area BA extends in one direction from the first non-display area NA1 toward the second non-display area NA2, at least a part of the link line LL disposed in the bending area BA may extend in a direction inclined with respect to one direction. In another example, at least a part of each of the plurality of link lines LL may have patterns with various shapes. For example, at least a part of each of the plurality of link lines LL disposed in the bending area BA may have a shape in which conductive patterns are repeatedly disposed and have at least one of a diamond shape, a rhombic shape, a trapezoidal wave shape, a triangular wave shape, a serrated wave shape, a sine wave shape, a circular shape, and an omega (Ω) shape. However, the embodiments of the present disclosure are not limited thereto. Therefore, in order to minimize or reduce stress concentrated on the plurality of link lines LL and minimize or reduce the occurrence of a crack caused by the stress, the plurality of link lines LL may have various shapes including the above-mentioned shapes. However, the embodiments of the present disclosure are not limited thereto.

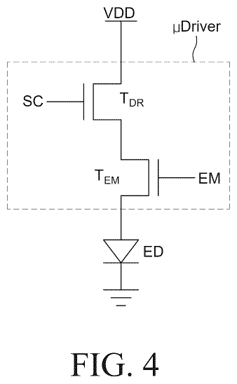

FIG. 4 is a view illustrating a circuit structure according to an embodiment of the present disclosure.

The pixel drive circuit PD may include a micro-driver μDriver. A micro-LED ED may be electrically connected to the micro-driver μDriver of the pixel drive circuit PD and operated. FIG. 4 illustrates that one micro-LED ED is connected to the micro-driver μDriver. However, the present disclosure is not limited thereto. For example, eight micro-LEDs ED may be connected to one micro-driver μDriver. In another example, sixteen micro-LEDs ED may be connected to one micro-driver Driver, or thirty-two micro-LEDs ED or sixty-four micro-LEDs ED may be simultaneously connected to one micro-driver μDriver.

One micro-driver Driver may include a driving transistor TDR and a light-emitting transistor TEM. However, the embodiments of the present disclosure are not limited thereto.

For example, a high-potential power voltage VDD may be applied to a first electrode of the driving transistor TDR, a first electrode of the light-emitting transistor TEM may be connected to a second electrode of the driving transistor TDR, and a scan signal SC may be applied to a gate electrode of the driving transistor TDR. The scan signal SC applied to the gate electrode of the driving transistor TDR may be direct current power, and a fixed reference voltage may be applied for each frame. However, the embodiments of the present disclosure are not limited thereto.

The second electrode of the driving transistor TDR may be connected to the first electrode of the light-emitting transistor TEM, the micro-LED ED may be connected to a second electrode of the light-emitting transistor TEM, and a light emission signal EM may be applied to a gate electrode of the light-emitting transistor TEM. The light emission signal EM applied to the gate electrode of the light-emitting transistor TEM may be a pulse width modulation signal that changes for each frame. However, the embodiments of the present disclosure are not limited thereto.

A first electrode of the micro-LED ED may be connected to the second electrode of the light-emitting transistor TEM, and a second electrode of the micro-LED ED may be connected to the ground. For example, the first electrode may be an anode electrode, and the second electrode may be a cathode electrode. However, the embodiments of the present disclosure are not limited thereto.

The driving transistor TDR and the light-emitting transistor TEM may each be an n-type transistor or a p-type transistor.

The driving transistor TDR may be turned on by the scan signal SC applied from the timing controller to the micro-driver Driver, and the light-emitting transistor TEM may be turned on by the light emission signal EM. Therefore, the drive current is applied to the micro-LED ED via the driving transistor TDR and the light-emitting transistor TEM by the high-potential power voltage VDD applied to the first electrode of the driving transistor TDR, such that the micro-LED ED may emit light.

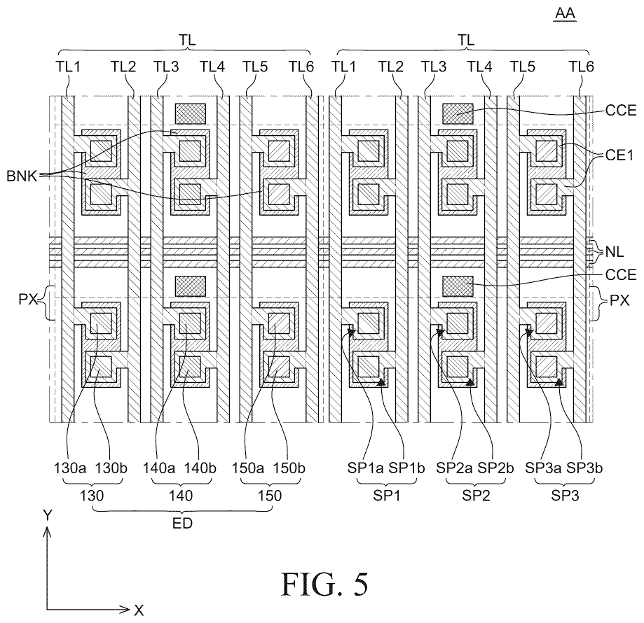

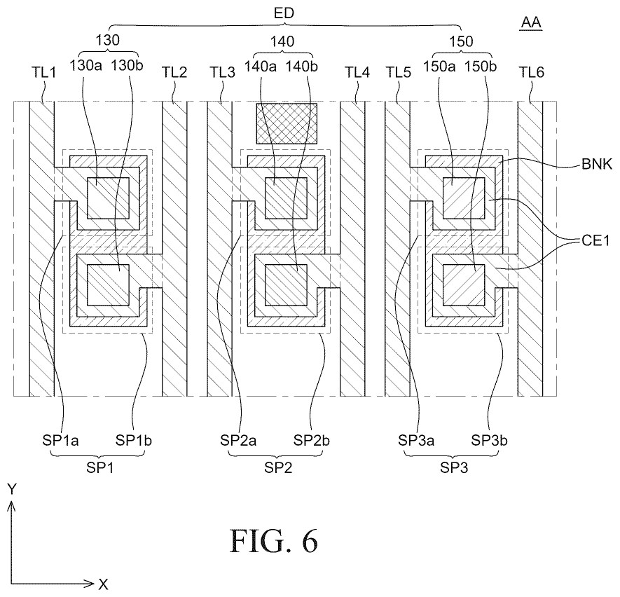

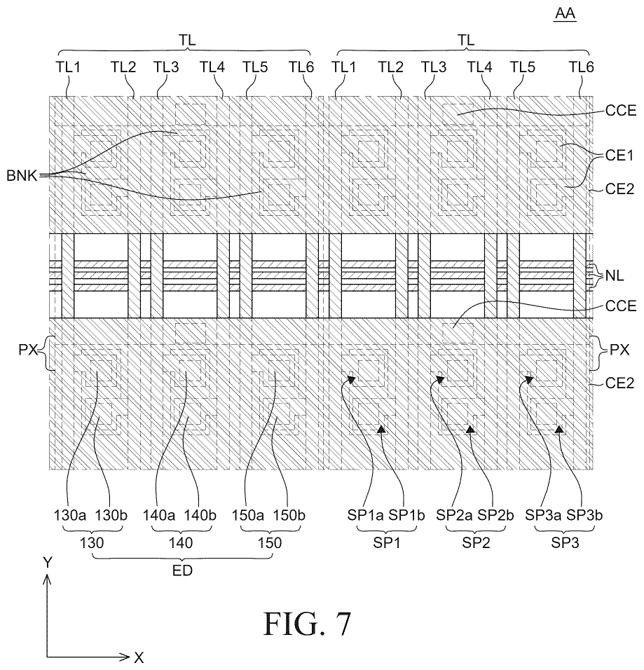

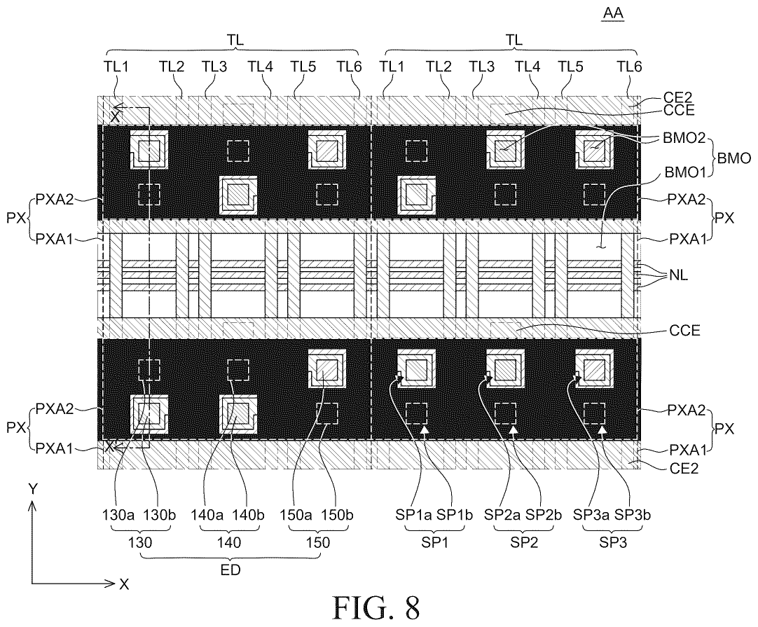

FIGS. 5 to 8 are top plan views of the display device according to an embodiment of the present disclosure. For example, FIG. 5 is an enlarged top plan view of a display area including a plurality of pixels. For example, FIG. 6 is an enlarged top plan view of a display area including a single pixel. For example, FIGS. 7 and 8 are enlarged top plan views of the display area including the plurality of pixels. FIGS. 5 and 6 illustrate a plurality of signal lines TL, a plurality of communication lines NL, a plurality of first electrodes CE1, a plurality of banks BNK, and a plurality of micro-LEDs ED. However, the embodiments of the present disclosure are not limited thereto. FIG. 7 is an enlarged top plan view illustrating a state in which a plurality of second electrodes CE2 is additionally disposed in FIG. 5. FIG. 8 is an enlarged top plan view illustrating a state in which the black matrix BM is additionally disposed in FIG. 7.

With reference to FIGS. 5 and 6, the plurality of pixels PX including the plurality of subpixels may be disposed in the display area AA.

First, with reference to FIG. 8 together, the plurality of pixels PX may each include a first area PXA1 that does not overlap (e.g., non-overlapping) the plurality of micro-LEDs ED, and a second area PXA2 that overlaps the plurality of micro-LEDs ED. For example, the second area PXA2 may overlap a first subpixel SP1, a second subpixel SP2, and a third subpixel SP3 in each of the plurality of pixels PX. In each of the plurality of pixels PX, the second area PXA2 may be an upper area of the pixel PX, and the first area PXA1 may be a lower area. With reference to FIG. 8, an area, which overlaps the plurality of micro-LEDs ED disposed at an upper side of one pixel PX, may be defined as the second area PXA2, and an area, which is disposed at a lower side of one pixel PX at which the plurality of micro-LEDs ED are not disposed, may be defined as the first area PXA1. However, the embodiments of the present disclosure are not limited thereto.

The first areas PXA1 of the plurality of pixels PX may be disposed between the second areas PXA2 of the plurality of pixels PX adjacent to one another in a second direction Y among the plurality of pixels PX. That is, the first areas PXA1 of the plurality of pixels PX and the second areas PXA2 of the plurality of pixels PX may be alternately disposed in the second direction Y. For example, the first areas PXA1 of the plurality of pixels PX may be connected to one another in a first direction X. The first areas PXA1 of the plurality of pixels PX may be disposed to be spaced apart from one another in the second direction Y. Meanwhile, the second areas PXA2 of the plurality of pixels PX may be connected to one another in the first direction X. The second areas PXA2 of the plurality of pixels PX may be areas defined as the first areas PXA1 are spaced apart from one another in the second direction Y.

The plurality of pixels PX may each have a square shape. For example, the plurality of pixels PX may each have a square shape having a horizontal length of 78 μm and a vertical length of 78 μm. However, the embodiments of the present disclosure are not limited thereto.

In each of the plurality of pixels PX, the first area PXA1 and the second area PXA2 may each have a rectangular shape. For example, in each of the plurality of pixels PX, the second area PXA2 may be defined as a rectangular area in which a length in the first direction X is longer than a length of the second direction Y. For example, the second area PXA2 may be a rectangular area of 78 μm×30 μm that overlaps the plurality of micro-LEDs ED. Meanwhile, the first area PXA1 may be an area excluding the second area PXA2 in each of the plurality of pixels PX. In each of the plurality of pixels PX, the first area PXA1 may be defined as a rectangular area in which a length in the first direction X is longer than a length in the second direction Y. For example, in each of the plurality of pixels PX, the length of the first area PXA1 in the second direction Y may be longer than the length of the second area PXA2 in the second direction Y. Further, the length of the first area PXA1 in the first direction X may be equal to the length of the second area PXA2 in the first direction X. Therefore, in each of the plurality of pixels PX1, an area of the first area PXA1 may be larger than an area of the second area PXA2. However, the embodiments of the present disclosure are not limited thereto.

The plurality of subpixels may each include the micro-LED ED and emit light independently. The plurality of subpixels may be disposed in a plurality of rows and a plurality of columns while defining a matrix shape. However, the embodiments of the present disclosure are not limited thereto.

The plurality of subpixels may include the first subpixel SP1, the second subpixel SP2, and the third subpixel SP3. For example, any one of the first subpixel SP1, the second subpixel SP2, and the third subpixel SP3 may be a red subpixel, another subpixel may be a green subpixel, and the remaining subpixel may be a blue subpixel. The types of plurality of subpixels are illustrative. However, the embodiments of the present disclosure are not limited thereto.

The plurality of pixels PX may each include one or more first subpixels SP1, one or more second subpixels SP2, and one or more third subpixels SP3. For example, one pixel PX may include a pair of first subpixels SP1, a pair of second subpixels SP2, and a pair of third subpixels SP3. The pair of first subpixels SP1 may include a first-first subpixel SPla and a first-second subpixel SP1b. The pair of second subpixels SP2 may include a second-first subpixel SP2a and a second-second subpixel SP2b. The pair of third subpixels SP3 may include a third-first subpixel SP3a and a third-second subpixel SP3b. For example, one pixel PX may include the first-first subpixel SP1a, the first-second subpixel SP1b, the second-first subpixel SP2a, the second-second subpixel SP2b, the third-first subpixel SP3a, and the third-second subpixel SP3b. However, the embodiments of the present disclosure are not limited thereto.

The plurality of subpixels constituting one pixel PX may be variously arranged. For example, in one pixel PX, the pair of first subpixels SP1 may be disposed in the same column, the pair of second subpixels SP2 may be disposed in the same column, and the pair of third subpixels SP3 may be disposed in the same column. The first subpixel SP1, the second subpixel SP2, and the third subpixel SP3 may be disposed in the same row. The number of and arrangement of the plurality of subpixels constituting one pixel PX are illustrative. However, the embodiments of the present disclosure are not limited thereto.

The plurality of signal lines TL may be disposed in areas between the plurality of subpixels. The plurality of signal lines TL may extend in the second direction Y between the plurality of subpixels. The plurality of signal lines TL may be lines configured to transmit an anode voltage from the pixel drive circuit PD to the plurality of subpixels. For example, the plurality of signal lines TL may be electrically connected to the plurality of pixel drive circuits PD and the first electrodes CE1 of the plurality of subpixels. The anode voltage outputted from the pixel drive circuit PD may be transmitted to the first electrodes CE1 of the plurality of subpixels through the plurality of signal lines TL. For example, the first electrode CE1 may be an electrode electrically connected to an anode electrode 134 of the micro-LED ED. Therefore, the anode voltage from the signal line TL may be transmitted to the anode electrode 134 of the micro-LED ED through the first electrode CE1.

Therefore, the structure of the display device 1000 may be simplified by using the pixel drive circuit PD into which a plurality of pixel circuits is integrated instead of forming a plurality of transistors and a plurality of storage capacitors in the plurality of subpixels. In addition, because the circuits respectively disposed in the plurality of subpixels are integrated into one pixel drive circuit PD, the high-efficiency operation with low power consumption may be performed.

The plurality of signal lines TL may include first signal lines TL1, second signal lines TL2, third signal lines TL3, fourth signal lines TL4, fifth signal lines TL5, and sixth signal lines TL6. The first signal line TL1 and the second signal line TL2 may each be electrically connected to each of the pair of first subpixels SP1. The third signal line TL3 and the fourth signal line TL4 may each be electrically connected to each of the pair of second subpixels SP2. The fifth signal line TL5 and the sixth signal line TL6 may each be electrically connected to each of the pair of third subpixels SP3.

The first signal line TL1 may be disposed at one side of the pair of first subpixels SP1, and the first signal line TL1 may be disposed at another side of the pair of first subpixels SP1. The first signal line TL1 may be electrically connected to one of the pair of first subpixels SP1, e.g., the first electrode CE1 of the first-first subpixel SP1a. The second signal line TL2 may be electrically connected to the remaining one of the pair of first subpixels SP1, e.g., the first electrode CE1 of the first-second subpixel SP1b.

The third signal line TL3 may be disposed at one side of the pair of second subpixels SP2, and the fourth signal line TLA may be disposed at another side of the pair of second subpixels SP2. For example, the third signal line TL3 may be disposed adjacent to the second signal line TL2. The third signal line TL3 may be electrically connected to one of the pair of second subpixels SP2, e.g., the first electrode CE1 of the second-first subpixel SP2a. The fourth signal line TL4 may be electrically connected to the remaining one of the pair of second subpixels SP2, e.g., the first electrode CE1 of the second-second subpixel SP2b.

The fifth signal line TL5 may be disposed at one side of the pair of third subpixels SP3, and the sixth signal line TL6 may be disposed at another side of the pair of third subpixels SP3. For example, the fifth signal line TL5 may be disposed adjacent to the fourth signal line TL4. The sixth signal line TL6 may be disposed adjacent to the first signal line TL1 connected to the adjacent pixel PX. The fifth signal line TL5 may be electrically connected to one of the pair of third subpixels SP3, e.g., the first electrode CE1 of the third-first subpixel SP3a. The sixth signal line TL6 may be electrically connected to the remaining one of the pair of third subpixels SP3, e.g., the first electrode CE1 of the third-second subpixel SP3b.

The plurality of signal lines TL may be made of an electrically conductive material. For example, the plurality of signal lines TL may be made of an electrically conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO). However, the embodiments of the present disclosure are not limited thereto. In another example, the plurality of signal lines TL may have a multilayer structure made of an electrically conductive material. For example, the plurality of signal lines TL may have a multilayer structure made of titanium (Ti), aluminum (Al), titanium (Ti), and indium tin oxide (ITO). However, the embodiments of the present disclosure are not limited thereto.

The plurality of communication lines NL may be disposed in areas between the plurality of pixels PX. The plurality of communication lines NL may be disposed to extend in the first direction X in the areas between the plurality of pixels PX. The plurality of communication lines NL may be disposed in the areas between the plurality of second electrodes CE2 and may not overlap the plurality of second electrodes CE2. For example, the plurality of communication lines NL may be lines used for short-range communication such as near field communication (NFC). The plurality of communication lines NL may serve as antennas. For example, the plurality of communication lines NL may be a plurality of connection lines and the like. However, the embodiments of the present disclosure are not limited thereto.

According to the present disclosure, the bank BNK may be disposed in each of the plurality of subpixels. The plurality of banks BNK may have structures on which the plurality of micro-LEDs ED is seated. The plurality of banks BNK may guide positions of the plurality of micro-LEDs ED during the process of transferring the plurality of micro-LEDs ED to the display device 1000. The plurality of micro-LEDs ED may be transferred onto the plurality of banks BNK during the process of transferring the plurality of micro-LEDs ED. The plurality of banks BNK may be bank patterns, structures, or the like. However, the embodiments of the present disclosure are not limited thereto.

The bank BNK of the first subpixel SP1, the bank BNK of the second subpixel SP2, and the bank BNK of the third subpixel SP3 may be disposed to be spaced apart from one another. The bank BNK of the first subpixel SP1, the bank BNK of the second subpixel SP2, and the bank BNK of the third subpixel SP3 may be configured to be separated from one another. Therefore, the banks BNK of the first subpixel SP1, the second subpixel SP2, and the third subpixel SP3, to which different types of micro-LEDs ED are transferred, may be easily identified.

The bank BNK of the first-first subpixel SP1a and the bank BNK of the first-second subpixel SP1b may be connected to each other, spaced apart from each other, or separated from each other. For example, the bank BNK of the first-first subpixel SP1a and the bank BNK of the first-second subpixel SP1b, on which the micro-LEDs ED of the same type are disposed, may be connected to each other, spaced apart from each other, or separated from each other in consideration of designs such as transfer process requirements. Further, the bank BNK of the second-first subpixel SP2a and the bank BNK of the second-second subpixel SP2b may be connected to each other, spaced apart from each other, or separated from each other. The bank BNK of the third-first subpixel SP3a and the bank BNK of the third-second subpixel SP3b may be connected to each other, spaced apart from each other, or separated from each other. Therefore, the banks BNK of the pair of first subpixels SP1, the banks BNK of the pair of second subpixels SP2, and the banks BNK of the pair of third subpixels SP3 may be variously formed. However, the embodiments of the present disclosure are not limited thereto.

For example, the plurality of banks BNK may made of an organic insulating material. The plurality of banks BNK may each be configured as a single layer or multilayer made of an organic insulating material. For example, the plurality of banks BNK may be made of photoresist, polyimide (PI), an acrylic material, or the like. However, the embodiments of the present disclosure are not limited thereto.

The first electrode CE1 may be disposed in each of the plurality of subpixels. The first electrode CE1 may be disposed on the bank BNK. The first electrode CE1 may be electrically connected to one of the plurality of signal lines TL. At least a part of the first electrode CE1 may extend to the outside of the bank BNK and be electrically connected to the signal line TL closest to the first electrode CE1. For example, a part of the first electrode CE1 of the first-first subpixel SP1a may extend to one side area of the first-first subpixel SP1a and be electrically connected to the first signal line TL1, and a part of the first electrode CE1 of the first-second subpixel SP1b may extend to the other side area of the first-second subpixel SP1b and be electrically connected to the second signal line TL2. A part of the first electrode CE1 of the second-first subpixel SP2a may extend to one side area of the second-first subpixel SP2a and be electrically connected to the third signal line TL3, and a part of the first electrode CE1 of the second-second subpixel SP2b may extend to the other side area of the second-second subpixel SP2b and be electrically connected to the fourth signal line TL4. A part of the first electrode CE1 of the third-first subpixel SP3a may extend to one side area of the third-first subpixel SP3a and be electrically connected to the fifth signal line TL5, and a part of the first electrode CE1 of the third-second subpixel SP3b may extend to the other side area of the third-second subpixel SP3b and be electrically connected to the sixth signal line TL6.

The first electrode CE1 may be electrically connected to the anode electrode 134 of the micro-LED ED and transmit the anode voltage from the pixel drive circuit PD to the micro-LED ED through the signal line TL. Different voltages may be applied to the first electrode CE1 of each of the plurality of subpixels in accordance with the displayed images. For example, different voltages may be applied to the first electrode CE1 of each of the plurality of subpixels. Therefore, the first electrode CE1 may be a pixel electrode. However, the embodiments of the present disclosure are not limited thereto.

The first electrode CE1 may be made of an electrically conductive material. For example, the first electrode CE1 may be integrated with the plurality of signal lines TL. For example, the first electrode CE1 may be made of the same electrically conductive material as the plurality of signal lines TL. However, the embodiments of the present disclosure are not limited thereto. For example, the first electrode CE1 may be made of an electrically conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO). However, the embodiments of the present disclosure are not limited thereto. In another example, the first electrode CE1 may have a multilayer structure made of an electrically conductive material. For example, the plurality of first electrodes CE1 may each have a multilayer structure made of titanium (Ti), aluminum (Al), titanium (Ti), and indium tin oxide (ITO). However, the embodiments of the present disclosure are not limited thereto.

The micro-LED ED may be disposed in each of the plurality of subpixels. The plurality of micro-LEDs ED may be disposed on the bank BNK and the first electrode CE1. The plurality of micro-LEDs ED may be disposed on the first electrode CE and electrically connected to the first electrode CE1. Therefore, the micro-LED ED may emit light by receiving the anode voltage from the pixel drive circuit PD through the signal line TL and the first electrode CE1.

The plurality of micro-LEDs ED may include first micro-LEDs 130, second micro-LEDs 140, and third micro-LEDs 150. The first micro-LED 130 may be disposed in the first subpixel SP1. The second micro-LED 140 may be disposed in the second subpixel SP2. The third micro-LED 150 may be disposed in the third subpixel SP3. For example, any one of the first micro-LED 130, the second micro-LED 140, and the third micro-LED 150 may be a red micro-LED, another micro-LED may be a green micro-LED, the other micro-LED may be a blue micro-LED. However, the embodiments of the present disclosure are not limited thereto. Therefore, light beams with various colors including the white color may be implemented by combining red light, green light, and blue light emitted from the plurality of micro-LEDs ED. The types of micro-LEDs ED are illustrative. However, the embodiments of the present disclosure are not limited thereto.

The first micro-LEDs 130 may include a first-first micro-LED 130a disposed in the first-first subpixel SP1a, and a first-second micro-LED 130b disposed in the first-second subpixel SP1b. The second micro-LEDs 140 may include a second-first micro-LED 140a disposed in the second-first subpixel SP2a, and a second-second micro-LED 140b disposed in the second-second subpixel SP2b. The third micro-LEDs 150 may include a third-first micro-LED 150a disposed in the third-first subpixel SP3a, and a third-second micro-LED 150b disposed in the third-second subpixel SP3b.

With reference to FIGS. 5, 6, and 7 together, the second electrode CE2 may be disposed in each of the plurality of subpixels. The second electrodes CE2 may be disposed on the plurality of micro-LEDs ED. The second electrodes CE2 may be electrically connected to the pixel drive circuit PD through a plurality of contact electrodes CCE.

For example, the second electrode CE2 may be electrically connected to a cathode electrode 135 of the micro-LED ED and transmit a cathode voltage from the pixel drive circuit PD to the micro-LED ED. The same cathode voltage may be applied to the second electrodes CE2 of the plurality of subpixels. For example, the same voltage may be applied to the second electrode CE2 and the cathode electrode 135 of the micro-LED ED in each of the plurality of subpixels. Therefore, the second electrode CE2 may be a common electrode. However, the embodiments of the present disclosure are not limited thereto.

At least some of the plurality of subpixels may share the second electrode CE2. At least some of the second electrodes CE2 of the plurality of subpixels may be electrically connected to one another. Because the same voltage is applied to the second electrodes CE2, at least some of the subpixels may use and share the second electrode CE2. For example, the second electrodes CE2 of the pixels PX of at least some of the plurality of pixels PX disposed in the same row may be connected to each other. For example, one second electrode CE2 may be disposed in each of the plurality of pixels PX. One second electrode CE2 may be disposed for each of n subpixels.

For example, some of the second electrodes CE2 of the plurality of subpixels may be disposed to be spaced apart or separated from one another. For example, the second electrodes CE2 connected to the pixels PX disposed in an n-th row and the second electrodes CE2 connected to the pixels PX disposed in an (n+1) the row may be disposed to be spaced apart or separated from one another. For example, the plurality of second electrodes CE2 may be disposed to be spaced apart from one another with the plurality of communication lines NL interposed therebetween and extending in the first direction X. Therefore, the number of subpixels may be larger than the number of second electrodes CE2. In another example, all the second electrodes CE2 in the plurality of subpixels may be connected to one another, and only one second electrode CE2 may be disposed on the substrate 110. However, the embodiments of the present disclosure are not limited thereto.

The plurality of second electrodes CE2 may be made of a transparent electrically conductive material. However, the embodiments of the present disclosure are not limited thereto. The plurality of second electrodes CE2 may be made of a transparent electrically conductive material, and the light emitted from the micro-LED ED may be directed toward an upper side of the second electrode CE2. For example, the second electrode CE2 may be made of a transparent electrically conductive material such as indium tin oxide (ITO), indium zinc oxide (IZO), or indium gallium zinc oxide (IGZO). However, the embodiments of the present disclosure are not limited thereto.

The plurality of contact electrodes CCE may be disposed on the substrate 110. For example, the plurality of contact electrodes CCE may be disposed to be spaced apart from the plurality of banks BNK and the plurality of signal lines TL. The plurality of second electrodes CE2 may each overlap at least one contact electrode CCE. For example, one second electrode CE2 may overlap the plurality of contact electrodes CCE.

For example, the plurality of contact electrodes CCE may be electrically connected to the plurality of second electrodes CE2. The plurality of contact electrodes CCE may be disposed between the substrate 110 and the plurality of second electrodes CE2 and transmit the cathode voltage from the pixel drive circuit PD to the second electrode CE2.

With reference to FIG. 8, the black matrix BM is disposed on the plurality of second electrodes CE2. The black matrix BM may minimize or reduce a color mixture of the light from the plurality of subpixels and minimize or reduce external light reflection.

The black matrix BM may be made of an opaque material. For example, the black matrix BM may be made of an organic insulating material to which a black pigment is added.

The black matrix BM includes one or more first transmission holes BMO1 disposed in the first area PXA1 of each of the plurality of pixels PX. The one or more first transmission holes BMO1 are opening portions disposed in the first area PXA1 of each of the plurality of pixels PX. The first transmission holes BMO1 may be disposed to overlap at least some of the plurality of second electrodes CE2 or at least some of the plurality of communication lines NL disposed in the first areas PXA1 of the plurality of pixels PX. Therefore, the plurality of second electrodes CE2 or the plurality of communication lines NL may be at least partially exposed by the first transmission holes BMO1.

The one or more first transmission holes BMO1 may have various planar shapes. For example, the planar shapes of the one or more first transmission holes BMO1 may be any one or more of a square shape, a rectangular shape, and a circular shape. In addition, when the first transmission holes BMO1 are provided as a plurality of first transmission holes BMO1, all the plurality of first transmission holes BMO1 may have the same shape or two or more different shapes.

In case that the first transmission holes BMO1 are provided as a plurality of first transmission holes BMO1, the plurality of first transmission holes BMO1 may be identical in area in a plan view. Alternatively, at least some of the plurality of first transmission holes BMO1 are identical in area in a plan view, and some of the other first transmission holes BMO1 may be different in area in a plan view. Alternatively, all the plurality of first transmission holes BMO1 may be different in area in a plan view.

An overall area of the one or more first transmission holes BMO1 in a plan view in each of the plurality of pixels PX may be about 61.54% or less of an overall area of the pixel PX including the one or more first transmission holes BMO1. However, the embodiments of the present disclosure are not limited thereto.

With reference to FIG. 8, one first transmission hole BMO1 may be disposed in the first area PXA1 in each of the plurality of pixels PX. An area of one first transmission hole BMO1 in a plan view may be equal to an area of the first area PXA1 in a plan view in each of the plurality of pixels PX. However, the present disclosure is not limited thereto. An area of one first transmission hole in a plan view may be smaller than an area of the first area in a plan view.

In addition, one first transmission hole BMO1 may completely overlap the first area PXA1 of each of the plurality of pixels PX. The black matrix BM may not be disposed in the first area PXA1 of each of the plurality of pixels PX. The entire first area PXA1 of each of the plurality of pixels PX may be one opening portion. Therefore, one first transmission hole BMO1 may expose components disposed below one first transmission hole BMO1. For example, all the communication lines NL disposed below the black matrix BM may be exposed by the first transmission holes BMO1 disposed in the plurality of pixels PX. In addition, at least some of the plurality of second electrodes CE2 may be exposed by the first transmission holes BMO1 disposed in the plurality of pixels PX. However, the embodiments of the present disclosure are not limited thereto.

The black matrix BM may further include a plurality of second transmission holes BMO2 disposed in the second area PXA2 of each of the plurality of pixels PX.

The plurality of second transmission holes BMO2 may be opening portions that overlap the micro-LEDs ED of the plurality of subpixels. The light emitted from the plurality of micro-LEDs ED may be extracted to the outside of the display panel 100 through the plurality of second transmission holes BMO2. The plurality of second transmission holes BMO2 may be disposed to overlap some of the plurality of subpixels included in one pixel PX.

The plurality of second transmission holes BMO2 may have larger sizes than the plurality of micro-LEDs ED. For example, the plurality of second transmission holes BMO2 are formed to be wider than the plurality of micro-LEDs ED in a plan view, which may ensure a margin against a process deviation.

A planar shape of each of the plurality of second transmission holes BMO2 may be a shape corresponding to a planar shape of each of the plurality of micro-LEDs ED. For example, in case that the planar shape of each of the plurality of micro-LEDs ED is a rectangular shape, the planar shape of each of the plurality of second transmission holes BMO2 may be a rectangular shape. However, the planar shape of each of the plurality of second transmission holes BMO2 and the planar shape of each of the plurality of micro-LEDs ED may be different from each other. However, the present disclosure is not limited thereto.

Meanwhile, the display device 1000 may be manufactured by forming the plurality of micro-LEDs ED on a wafer and transferring the micro-LEDs ED to the substrate 110 of the display device 1000. Various types of defects may occur during the process of transferring the plurality of micro-LEDs ED having fine sizes to the substrate 110 as described above. For example, a non-transfer defect, which is caused when the micro-LEDs ED are not transferred, may occur in some of the subpixels, and a defect, in which the micro-LEDs ED are transferred while deviating from exact positions, may occur because of alignment errors in some of the subpixels. In addition, the transferred micro-LED ED may be defective even though the transfer process is normally performed. Therefore, the plurality of micro-LEDs ED of the same type may be transferred to one subpixel in consideration of defects occurring during the process of transferring the plurality of micro-LEDs ED. A lighting inspection may be performed on the plurality of micro-LEDs ED, and only one micro-LED ED, which is finally determined as being normal, may be used.

For example, both the first-first micro-LED 130a and the first-second micro-LED 130b are transferred to one subpixel, and whether the first-first micro-LED 130a and the first-second micro-LED 130b are defective may be inspected. If both the first-first micro-LED 130a and the first-second micro-LED 130b are determined as being normal, the first-first micro-LED 130a may be used, and the first-second micro-LED 130b may not be used. In another example, in case that the first-second micro-LED 130b between the first-first micro-LED 130a and the first-second micro-LED 130b is determined as being normal, the first-first micro-LED 130a may not be used, and the first-second micro-LED 130b may be used. Therefore, even though the plurality of micro-LEDs ED of the same type is transferred to one subpixel, only one micro-LED ED may be finally used.

Therefore, any one of the pair of micro-LEDs ED may be a main (main or primary) micro-LED ED, and the other of the micro-LEDs ED may be a redundancy micro-LED ED. The redundancy micro-LED ED may be an extra micro-LED ED transferred to prepare for a defect of the main micro-LED ED. When the main micro-LED ED is defective, the redundancy micro-LED ED may be used instead of the main micro-LED ED. Therefore, both the main micro-LED ED and the redundancy micro-LED ED are transferred to one subpixel, which may minimize or reduce a deterioration in display quality caused by defects of the main micro-LED ED and the redundancy micro-LED ED.

For example, the first-first micro-LED 130a, the second-first micro-LED 140a, and the third-first micro-LED 150a transferred to one pixel PX may be used as the main micro-LEDs ED, and the first-second micro-LED 130b, the second-second micro-LED 140b, and the third-second micro-LED 150b may be used as the redundancy micro-LEDs ED.

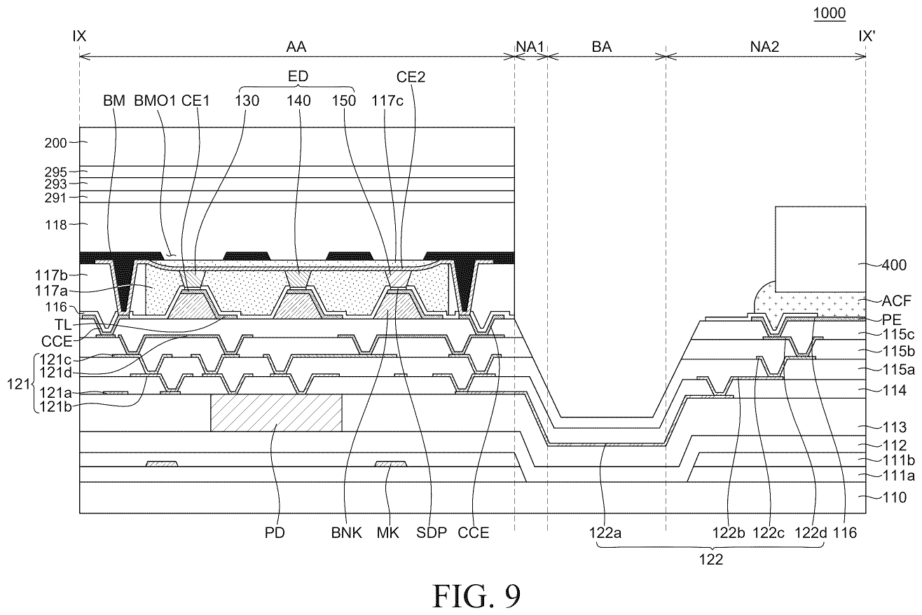

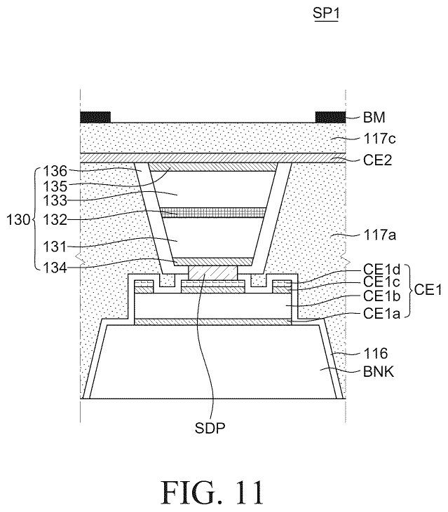

FIG. 9 is a cross-sectional view taken along line IX-IX′ in FIG. 3 according to an embodiment of the present disclosure. FIG. 10 is a cross-sectional view taken along line X-X′ in FIG. 8 according to an embodiment of the present disclosure. FIG. 11 is a cross-sectional view of the display device according to an embodiment of the present disclosure. For example, FIG. 9 is a cross-sectional view of the display area AA, the first non-display area NA1, the bending area BA, and the second non-display area NA2. For example, FIG. 10 is a cross-sectional view of the display area AA. For example, FIG. 11 is an enlarged cross-sectional view of the first subpixel.

With reference to FIGS. 9 and 10, a first buffer layer 111a and a second buffer layer 111b may be disposed in the remaining area of the substrate 110, except for the bending area BA.

The first buffer layer 111a and the second buffer layer 111b may be disposed in the display area AA, the first non-display area NA1, and the second non-display area NA2. The first buffer layer 111a and the second buffer layer 111b may reduce the permeation of moisture or impurities through the substrate 110. The first buffer layer 111a and the second buffer layer 111b may be made of an inorganic insulating material. For example, the first buffer layer 111a and the second buffer layer 111b may each be configured as a single layer or multilayer made of silicon oxide (SiOx) or silicon nitride (SiNx). However, the embodiments of the present disclosure are not limited thereto.

For example, the first buffer layer 111a and the second buffer layer 111b disposed in the bending area BA may be partially removed. A top surface of the substrate 110 positioned in the bending area BA may be exposed from the first buffer layer 111a and the second buffer layer 111b. The first buffer layer 111a and the second buffer layer 111b, which are made of an inorganic insulating material, are removed from the bending area BA, which may minimize or reduce the occurrence of a crack in the first buffer layer 111a and the second buffer layer 111b that may be caused when the bending area BA is bent.

A plurality of alignment keys MK may be disposed between the first buffer layer 111a and the second buffer layer 111b. The plurality of alignment keys MK may be configured to identify a position of the pixel drive circuit PD during the process of manufacturing the display device 1000. For example, the plurality of alignment keys MK may be configured to align the position of the pixel drive circuit PD transferred onto a bonding layer 112. In another example, the plurality of alignment keys MK may be excluded.

The bonding layer 112 may be disposed on the second buffer layer 111b. The bonding layer 112 may be disposed in the display area AA, the first non-display area NA1, the bending area BA, and the second non-display area NA2. In another example, at least a part of the bonding layer 112 may be removed from the non-display area NA including the bending area BA. For example, the bonding layer 112 may be made of any one of polymer (adhesive polymer), epoxy resin, UV-curable resin, polyimide, acrylate, urethane, and polydimethylsiloxane (PDMS). However, the embodiments of the present disclosure are not limited thereto.

The pixel drive circuit PD may be disposed on the bonding layer 112 in the display area AA. In case that the pixel drive circuit PD is implemented as an operation driver, the operation driver may be mounted on the bonding layer 112 by the transfer process. However, the embodiments of the present disclosure are not limited thereto.

A first protective layer 113 may be disposed on the bonding layer 112 and the pixel drive circuit PD. The first protective layer 113 may be disposed to surround a side surface of the pixel drive circuit PD. However, the embodiments of the present disclosure are not limited thereto. For example, the first protective layer 113 may be disposed to cover at least a part of a top surface of the pixel drive circuit PD. For example, the first protective layer 113 may be entirely disposed in the display area AA and the non-display area NA. However, the embodiments of the present disclosure are not limited thereto. For example, a part of the first protective layer 113 disposed in the bending area BA may be removed.

The first protective layer 113 may be provided as a plurality of first protective layers 113. For example, in case that the first protective layer 113 is provided as a plurality of first protective layers 113, at least one layer may be entirely disposed in the display area AA, the bending area BA, and the non-display areas NA1 and NA2. Further, another layer may be partially disposed in the display area AA, the first non-display area NA1, and the second non-display area NA2. However, the embodiments of the present disclosure are not limited thereto.

The first protective layer 113 may be made of an organic insulating material. However, the embodiments of the present disclosure are not limited thereto. For example, the first protective layer 113 may be made of photoresist, polyimide (PI), or a photo acrylic material. However, the embodiments of the present disclosure are not limited thereto. For example, the first protective layer 113 may be an overcoating layer or an insulation layer. However, the embodiments of the present disclosure are not limited thereto.

According to the present disclosure, a plurality of first connection lines 121 may be disposed on the first protective layer 113 in the display area AA. The plurality of first connection lines 121 may be lines configured to electrically connect the pixel drive circuit PD to other constituent elements. For example, the pixel drive circuit PD may be electrically connected to the plurality of signal lines TL, the plurality of contact electrodes CCE, and the like through the plurality of first connection lines 121. For example, the plurality of first connection lines 121 may include first-first connection lines 121a, first-second connection lines 121b, first-third connection lines 121c, and first-fourth connection lines 121d. However, the embodiments of the present disclosure are not limited thereto.

For example, the plurality of first-first connection lines 121a may be disposed on the first protective layer 113. The plurality of first-first connection lines 121a may be electrically connected to the pixel drive circuit PD. The plurality of first-first connection lines 121a may transmit a voltage, which is outputted from the pixel drive circuit PD, to the first electrode CE1 or the second electrode CE2.

For example, a second protective layer 114 may be disposed on the first protective layer 113. The second protective layer 114 may be entirely disposed in the display area AA and the non-display area NA. In the bending area BA, the second protective layer 114 may cover or surround a top surface of the first protective layer 113. The second protective layer 114 may be made of an organic insulating material. For example, the second protective layer 114 may be made of photoresist, polyimide (PI), or a photo acrylic material. However, the embodiments of the present disclosure are not limited thereto. For example, the first protective layer 113 and the second protective layer 114 may be made of the same material. However, the embodiments of the present disclosure are not limited thereto.

The plurality of first-second connection lines 121b may be disposed on the second protective layer 114. The plurality of first-second connection lines 121b may be connected indirectly or directly to the pixel drive circuit PD. For example, a part of the first-second connection line 121b may be connected directly to the pixel drive circuit PD through a contact hole of the second protective layer 114. Another part of the first-second connection line 121b may be electrically connected to the first-first connection line 121a through the contact hole of the second protective layer 114. However, the embodiments of the present disclosure are not limited thereto. The voltage outputted from the pixel drive circuit PD may be transmitted to the first electrode CE1 or the second electrode CE2 through a connection line different from the plurality of first-second connection lines 121b.

A first insulation layer 115a may be disposed on the plurality of first-second connection lines 121b. The first insulation layer 115a may be entirely disposed in the display area AA and the non-display area NA. However, the embodiments of the present disclosure are not limited thereto. The first insulation layer 115a may be made of an organic insulating material. However, the embodiments of the present disclosure are not limited thereto. For example, the first insulation layer 115a may be made of photoresist, polyimide (PI), or a photo acrylic material. However, the embodiments of the present disclosure are not limited thereto.

The plurality of first-third connection lines 121c may be disposed on the first insulation layer 115a. The plurality of first-third connection lines 121c may be electrically connected to the plurality of first-second connection lines 121b. For example, the first-third connection line 121c may be electrically connected to the first-second connection line 121b through a contact hole of the first insulation layer 115a.

A second insulation layer 115b may be disposed on the plurality of first-third connection lines 121c. The second insulation layer 115b may be disposed in the remaining area, except for the bending area BA. However, the embodiments of the present disclosure are not limited thereto. The second insulation layer 115b may be disposed in the display area AA, the first non-display area NA1, and the second non-display area NA2. However, the embodiments of the present disclosure are not limited thereto. For example, a part of the second insulation layer 115b disposed in the bending area BA may be removed. The second insulation layer 115b may be made of an organic insulating material. However, the embodiments of the present disclosure are not limited thereto. For example, the second insulation layer 115b may be made of photoresist, polyimide (PI), or a photo acrylic material. However, the embodiments of the present disclosure are not limited thereto.

The plurality of first-fourth connection lines 121d may be disposed on the second insulation layer 115b. The plurality of first-fourth connection lines 121d may be electrically connected to the plurality of first-third connection lines 121c. For example, the first-fourth connection line 121d may be electrically connected to the first-third connection line 121c through the contact hole of the second insulation layer 115b.

According to the present disclosure, a plurality of second connection lines 122 may be disposed on the first protective layer 113 in the non-display area NA. The plurality of second connection lines 122 may be lines configured to transmit the signals, which are transmitted to the pad part PAD from the flexible circuit board (or flexible film) 400 and the printed circuit board 500 (see FIG. 1), to the pixel drive circuit PD in the display area AA. For example, the plurality of second connection lines 122 may be electrically connected to the plurality of pad electrodes PE and receive the signals from the flexible circuit board (or flexible film) 400 and the printed circuit board 500.

For example, the plurality of second connection lines 122 may extend from the pad part PAD toward the display area AA and transmit signals to the lines in the display area AA. In this case, the plurality of second connection lines 122 may serve as the link lines LL. The plurality of second connection lines 122 may include second-first connection lines 122a, second-second connection lines 122b, second-third connection lines 122c, and second-fourth connection lines 122d.

The plurality of second-first connection lines 122a may be disposed on the first protective layer 113. The plurality of second-first connection lines 122a may extend from the second non-display area NA2 to the bending area BA and the first non-display area NA1. The plurality of second-first connection lines 122a may transmit the signals, which are transmitted to the pad part PAD from the flexible circuit board (or flexible film) 400 and the printed circuit board 500, to the pixel drive circuit PD in the display area AA. For example, the plurality of second-first connection lines 122a may be disposed on the same layer as the plurality of first-first connection lines 121a. For example, the plurality of second-first connection lines 122a may be made of the same material as the plurality of first-first connection lines 121a.

The plurality of second-second connection lines 122b may be disposed on the second protective layer 114. The plurality of second-second connection lines 122b may be disposed in the second non-display area NA2. The second-second connection line 122b may be electrically connected to the second-first connection line 122a through the contact hole of the second protective layer 114. Therefore, the signals may be transmitted from the flexible circuit board (or flexible film) 400 and the printed circuit board to the second-first connection line 122a through the second-second connection line 122b. For example, the plurality of second-second connection lines 122b may be disposed on the same layer as the plurality of first-second connection lines 121b. For example, the plurality of second-second connection lines 122b may be made of the same material as the plurality of first-second connection lines 121b.

The second-third connection line 122c may be disposed on the first insulation layer 115a. The second-third connection line 122c may be disposed in the second non-display area NA2. The second-third connection line 122c may be electrically connected to the second-second connection line 122b through the contact hole of the first insulation layer 115a. Therefore, the signals may be transmitted from the flexible circuit board (or flexible film) 400 and the printed circuit board 500 to the second-first connection line 122a through the second-third connection line 122c and the second-second connection line 122b. For example, the plurality of second-third connection lines 122c may be disposed on the same layer as the plurality of first-third connection lines 121c. For example, the plurality of second-third connection lines 122c may be made of the same material as the plurality of first-third connection lines 121c.

The second-fourth connection line 122d may be disposed on the second insulation layer 115b. The second-fourth connection line 122d may be disposed in the second non-display area NA2. The second-fourth connection line 122d may be electrically connected to the second-third connection line 122c through the contact hole of the second insulation layer 115b. Therefore, the signals may be transmitted from the flexible circuit board (or flexible film) 400 and the printed circuit board 500 to the second-first connection line 122a through the second-fourth connection line 122d, the second-third connection line 122c, and the second-second connection line 122b. For example, the plurality of second-fourth connection lines 122d may be disposed on the same layer as the plurality of first-fourth connection lines 121d. For example, the plurality of second-fourth connection lines 122d may be made of the same material as the plurality of first-fourth connection lines 121d.

The plurality of first connection lines 121 and the plurality of second connection lines 122 may be made of any one of electrically conductive materials with excellent flexibility or various electrically conductive materials used for the display area AA. For example, the second connection line 122 partially disposed in the bending area BA may be made of an electrically conductive material, such as gold (Au), silver (Ag), or aluminum (Al), that is excellent in flexibility. However, the embodiments of the present disclosure are not limited thereto. In another example, the plurality of first connection lines 121 and the plurality of second connection lines 122 may be made of molybdenum (Mo), chromium (Cr), titanium (Ti), nickel (Ni), neodymium (Nd), copper (Cu), and an alloy of silver (Ag) and magnesium (Mg), or an alloy thereof. However, the embodiments of the present disclosure are not limited thereto.

A third insulation layer 115c may be disposed on the plurality of first connection lines 121 and the plurality of second connection lines 122. The third insulation layer 115c may be disposed in the remaining area, except for the bending area BA. However, the embodiments of the present disclosure are not limited thereto. The third insulation layer 115c may be disposed in the display area AA, the first non-display area NA1, and the second non-display area NA2. A part of the third insulation layer 115c disposed in the bending area BA may be removed. The third insulation layer 115c may be made of an organic insulating material. However, the embodiments of the present disclosure are not limited thereto. For example, the third insulation layer 115c may be made of photoresist, polyimide (PI), or a photo acrylic material. However, the embodiments of the present disclosure are not limited thereto.

The plurality of banks BNK may be disposed on the third insulation layer 115c in the display area AA. The plurality of banks BNK may be disposed to overlap the plurality of subpixels. One or more micro-LEDs ED of the same type may be disposed above the plurality of banks BNK.

The plurality of signal lines TL may be disposed on the third insulation layer 115c in the display area AA. The plurality of signal lines TL may be disposed in areas between the plurality of banks BNK. For example, the plurality of signal lines TL may be disposed adjacent to any one of the plurality of banks BNK.

The plurality of contact electrodes CCE may be disposed on the third insulation layer 115c in the display area AA. The plurality of contact electrodes CCE may supply the cathode voltage from the pixel drive circuit PD to the second electrode CE2.

The first electrode CE1 may be disposed on the bank BNK. For example, the first electrode CE1 may be disposed to extend from the adjacent signal line TL to the upper side of the bank BNK. The first electrode CE1 may be disposed on the top surface of the bank BNK and the side surface of the bank BNK. For example, the first electrode CE1 may be disposed to extend from the signal line TL on the top surface of the third insulation layer 115c to the side surface of the bank BNK and the top surface of the bank BNK.

With reference to FIG. 11, the first electrode CE1 may include a plurality of conductive layers. For example, the first electrode CE1 may include a first conductive layer CEla, a second conductive layer CE1b, a third conductive layer CElc, and a fourth conductive layer CEld. However, the embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, the first conductive layer CE1a, the second conductive layer CE1b, the third conductive layer CE1c, and the fourth conductive layer CE1d may each be made of titanium (Ti), molybdenum (Mo), aluminum (Al), titanium (Ti), or indium tin oxide (ITO). However, the embodiments of the present disclosure are not limited thereto.

According to the present disclosure, among the plurality of conductive layers constituting the first electrode CE1, some conductive layers with high reflection efficiency may include alignment keys for aligning the micro-LEDs ED, and/or reflective plates. For example, among the plurality of conductive layers of the first electrode CE1, the second conductive layer CE1b may include a reflective material. For example, the second conductive layer CE1b may include aluminum (Al). However, the embodiments of the present disclosure are not limited thereto. Therefore, the second conductive layer CE1b may be configured as a reflective plate. In addition, with the high reflection efficiency of the second conductive layer CE1b, the second conductive layer CElb may be easily identified during the manufacturing process. Therefore, the position or transfer position of the micro-LED ED may be aligned with respect to the second conductive layer CE1b.

For example, in order to configure the second conductive layer CElb as a reflective plate, the third conductive layer CE1c and the fourth conductive layer CE1d, which cover the second conductive layer CE1b, may be partially removed or etched. For example, the third conductive layer CE1c and the fourth conductive layer CE1d disposed on the bank BNK may be partially removed or etched, such that a top surface of the second conductive layer CElb may be exposed. For example, central portions and rim portions (or edge portions) of the third conductive layer CE1c and the fourth conductive layer CE1d where solder patterns SDP are disposed may be maintained, and the remaining portions excluding the above-mentioned portions may be removed. For example, the rim portion (or edge portion) of the third conductive layer CE1c made of titanium (Ti) and the rim portion (or edge portion) of the fourth conductive layer CE1d made of indium tin oxide (ITO) may not be etched. Therefore, it is possible to inhibit or reduce the other conductive layers of the first electrode CE1 from being corroded by a tetramethyl ammonium hydroxide (TMAH) solution used for a mask process for the first electrode CE1.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer made of indium tin oxide (ITO) or indium zinc oxide (IZO) having high bondability to the solder pattern SDP and having corrosion resistance and acid resistance. However, the embodiments of the present disclosure are not limited thereto.

The first conductive layer CE1a, the second conductive layer CE1b, the third conductive layer CE1c, and the fourth conductive layer CE1d may be sequentially deposited and then patterned by a photolithography process and an etching process. However, the embodiments of the present disclosure are not limited thereto.

According to the present disclosure, the signal line TL, the contact electrode CCE, and the pad electrode PE disposed on the same layer as the first electrode CE1 may each be configured as a multilayer made of an electrically conductive material. However, the embodiments of the present disclosure are not limited thereto. For example, the signal line TL, the contact electrode CCE, and the pad electrode PE may each be configured as a multilayer made of indium tin oxide (ITO), titanium (Ti), aluminum (Al), and titanium (Ti). However, the embodiments of the present disclosure are not limited thereto.

According to the present disclosure, the solder pattern SDP may be disposed on the first electrode CE1 in each of the plurality of subpixels. The solder pattern SDP may electrically connect the first electrode CE1 and the micro-LED ED by bonding the micro-LED ED to the first electrode CE1. For example, the first electrode CE1 and the anode electrode 134 of the micro-LED ED may be electrically connected by eutectic bonding using the solder pattern SDP. However, the embodiments of the present disclosure are not limited thereto. For example, in case that the solder pattern SDP is made of indium (In) and the anode electrode 134 of the micro-LED ED is made of gold (Au), the solder pattern SDP and the anode electrode 134 may be joined by applying heat and pressure during the process of transferring the micro-LED ED. The micro-LED ED may be joined to the solder pattern SDP and the first electrode CE1 by eutectic bonding without a separate bonding material. For example, the solder pattern SDP may be made of indium (In), tin (Sn), or an alloy thereof. However, the embodiments of the present disclosure are not limited thereto. For example, the solder pattern SDP may be a bonding pad or a joining pad. However, the embodiments of the present disclosure are not limited thereto.

According to the present disclosure, a passivation layer 116 may be disposed on the plurality of signal lines TL, the plurality of first electrodes CE1, the plurality of contact electrodes CCE, and the third insulation layer 115c. For example, the passivation layer 116 may be disposed in the display area AA, the first non-display area NA1, and the second non-display area NA2. A part of the passivation layer 116 disposed in the bending area BA may be removed. A part of the passivation layer 116, which covers the plurality of pad electrodes PE in the second non-display area NA2, may be removed. The passivation layer 116 is disposed to cover the remaining area excluding the areas in which the bending area BA, the plurality of pad electrodes PE, and the solder pattern SDP are disposed, and as a result, it is possible to the permeation of moisture or impurities introduced into the micro-LED ED. For example, the passivation layer 116 may be configured as a single layer or multilayer made of silicon oxide (SiOx) or silicon nitride (SiNx). However, the embodiments of the present disclosure are not limited thereto. For example, the passivation layer 116 may be a protective layer, an insulation layer, or the like. However, the embodiments of the present disclosure are not limited thereto. For example, the passivation layer 116 may include a hole through which the solder pattern SDP is exposed.

In each of the plurality of subpixels, the micro-LED ED may be disposed on the solder pattern SDP. The first micro-LED 130 may be disposed in the first subpixel SP1. The second micro-LED 140 may be disposed in the second subpixel SP2. The third micro-LED 150 may be disposed in the third subpixel SP3.

The micro-LED ED may be formed on a silicon wafer by a method such as metal-organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering. However, the embodiments of the present disclosure are not limited thereto.

With reference to FIG. 11, the first micro-LED 130 may include the anode electrode 134, a first semiconductor layer 131, an active layer 132, a second semiconductor layer 133, the cathode electrode 135, and an encapsulation film 136. However, the embodiments of the present disclosure are not limited thereto. For example, the first micro-LED 130 may not include the encapsulation film 136.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented as a III-V group or II-VI group compound semiconductor and doped with impurities (or dopant). For example, one of the first semiconductor layer 131 and the second semiconductor layer 133 may be a semiconductor layer doped with n-type impurities, and the other of the first semiconductor layer 131 and the second semiconductor layer 133 may be a semiconductor layer doped with p-type impurities. However, the embodiments of the present disclosure are not limited thereto. For example, one of or both the first semiconductor layer 131 and the second semiconductor layer 133 may be layers made by doping a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs) with n-type or p-type impurities. However, the embodiments of the present disclosure are not limited thereto. For example, the n-type impurity may be silicon (Si), germanium (Ge), selenium (Se), carbon (C), tellurium (Te), tin (Sn), or the like. However, the embodiments of the present disclosure are not limited thereto. For example, the p-type impurity may be magnesium (Mg), zinc (Zn), calcium (Ca), strontium (Sr), barium BA, beryllium (Be), or the like. However, the embodiments of the present disclosure are not limited thereto.

For example, the first semiconductor layer 131 and the second semiconductor layer 133 may be respectively a nitride semiconductor containing n-type impurities and a nitride semiconductor containing p-type impurities. However, the embodiments of the present disclosure are not limited thereto. For example, the first semiconductor layer 131 may be a nitride semiconductor containing p-type impurities, and the second semiconductor layer 133 may be a nitride semiconductor containing n-type impurities. However, the embodiments of the present disclosure are not limited thereto.

The active layer 132 may be disposed between the first semiconductor layer 131 and the second semiconductor layer 133. The active layer 132 may emit light by receiving positive holes and electrons from the first semiconductor layer 131 and the second semiconductor layer 133. For example, the active layer 132 may have any one of a single well structure, a multi-well structure, a single quantum well structure, a multi-quantum well (MQW) structure, a quantum dot structure, and a quantum line structure. However, the embodiments of the present disclosure are not limited thereto. For example, the active layer 132 may be made of indium gallium nitride (InGaN), gallium nitride (GaN), or the like. However, the embodiments of the present disclosure are not limited thereto.

In another example, the active layer 132 may include a multi-quantum well (MQW) structure having a well layer, and a barrier layer having a higher band gap than the well layer. For example, the active layer 132 may configure an InGaN layer as the well layer and configure an AlGaN layer as the barrier layer. However, the embodiments of the present disclosure are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage outputted from the pixel drive circuit PD may be applied to the first semiconductor layer 131 through the signal line TL, the first electrode CE1, and the anode electrode 134. For example, the anode electrode 134 may be made of an electrically conductive material that may be bonded to the solder pattern SDP by eutectic bonding. However, the embodiments of the present disclosure are not limited thereto. For example, the anode electrode 134 may be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof. However, the embodiments of the present disclosure are not limited thereto.

The cathode electrode 135 may be disposed on the second semiconductor layer 133. For example, the cathode electrode 135 may electrically connect the second semiconductor layer 133 and the second electrode CE2. The cathode voltage outputted from the pixel drive circuit PD may be applied to the second semiconductor layer 133 through the contact electrode CCE, the second electrode CE2, and the cathode electrode 135. The cathode electrode 135 may be made of a transparent electrically conductive material so that the light emitted from the micro-LED ED may propagate to the upper side of the micro-LED ED. However, the embodiments of the present disclosure are not limited thereto. For example, the cathode electrode 135 may be made of a material such as indium tin oxide (ITO), indium zinc oxide (IZO), or indium gallium zinc oxide (IGZO). However, the embodiments of the present disclosure are not limited thereto.

The encapsulation film 136 may be at least partially disposed on the first semiconductor layer 131, the active layer 132, the second semiconductor layer 133, the anode electrode 134, and the cathode electrode 135. For example, the encapsulation film 136 may at least partially surround the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133.

For example, the encapsulation film 136 may be disposed on at least a part of the anode electrode 134 and at least a part of the cathode electrode 135, e.g., an edge portion (or edge portion or one side) of the anode electrode 134 and an edge portion (or edge portion or one side) of the cathode electrode 135. At least a part of the anode electrode 134 may be exposed from the encapsulation film 136, such that the anode electrode 134 and the solder pattern SDP may be connected. For example, at least a part of the cathode electrode 135 may be exposed from the encapsulation film 136, such that the cathode electrode 135 and the second electrode CE2 may be connected. For example, the encapsulation film 136 may be made of an insulating material such as silicon nitride (SiNx) or silicon oxide (SiOx). However, the embodiments of the present disclosure are not limited thereto.

In another example, the encapsulation film 136 may have a structure in which a reflective material is dispersed in a resin layer. However, the embodiments of the present disclosure are not limited thereto. For example, the encapsulation film 136 may be manufactured as a reflector having various structures. However, the embodiments of the present disclosure are not limited thereto. The light emitted from the active layer 132 is reflected upward by the encapsulation film 136, which may improve the light extraction efficiency. For example, the encapsulation film 136 may be a reflective layer. However, the embodiments of the present disclosure are not limited thereto.

According to the present disclosure, the micro-LED ED may have a vertical structure. However, the embodiments of the present disclosure are not limited thereto. For example, the micro-LED ED may have a lateral structure or a flip chip structure.

The first micro-LED 130 has been described with reference to FIG. 11. The second micro-LED 140 and the third micro-LED 150 may have substantially the same structure as the first micro-LED 130. For example, the first semiconductor layer 131, the active layer 132, the second semiconductor layer 133, the anode electrode 134, the cathode electrode 135, and the encapsulation film 136 of the first micro-LED 130 may be substantially identical to those of the second micro-LED 140 and the third micro-LED 150.

According to the present disclosure, first optical layers 117a may be disposed to surround the plurality of micro-LEDs ED in the display area AA. For example, the first optical layers 117a may be disposed to cover the plurality of micro-LEDs ED and the bank BNK in the areas of the plurality of subpixels. For example, the first optical layer 117a may cover the bank BNK, a part of the passivation layer 116, and the portions between the plurality of micro-LEDs ED. The first optical layers 117a may be disposed between the plurality of micro-LEDs ED included in one pixel PX and between the plurality of banks BNK or cover the plurality of micro-LEDs ED and the plurality of banks BNK. For example, the first optical layers 117a may extend in the first direction X and be disposed to be spaced apart from each other in the second direction Y. For example, the first optical layer 117a may be disposed between the passivation layer 116 and the second electrode CE2 and surround a lateral portion of the micro-LED ED and a lateral portion of the bank BNK. However, the embodiments of the present disclosure are not limited thereto. For example, the first optical layer 117a may be a diffusion layer, a sidewall diffusion layer, or the like. However, the embodiments of the present disclosure are not limited thereto.

The first optical layer 117a may include an organic insulating material in which fine particles are dispersed. However, the embodiments of the present disclosure are not limited thereto. For example, the first optical layer 117a may be made of siloxane in which fine metal particles such as titanium dioxide (TiO₂) particles are dispersed. However, the embodiments of the present disclosure are not limited thereto. The light emitted from the plurality of micro-LEDs ED may be scattered by the fine particles dispersed in the first optical layer 117a, and the light may be discharged to the outside of the display device 1000. Therefore, the first optical layer 117a may improve the efficiency in extracting light emitted from the plurality of micro-LEDs ED.

For example, the first optical layer 117a may be respectively disposed in the plurality of pixels PX or disposed together with some of the pixels PX disposed in the same row. However, the embodiments of the present disclosure are not limited thereto. For example, the first optical layer 117a may be disposed in each of the plurality of pixels PX, or the plurality of pixels PX may share one first optical layer 117a. In another example, the plurality of subpixels may each separately include the first optical layer 117a. However, the embodiments of the present disclosure are not limited thereto.

According to the present disclosure, a second optical layer 117b may be disposed on the passivation layer 116 in the display area AA. For example, the second optical layer 117b may be disposed to surround the first optical layer 117a. For example, the second optical layer 117b may adjoin a side surface of the first optical layer 117a. For example, the second optical layer 117b may be disposed in an area between the plurality of pixels PX. However, the embodiments of the present disclosure are not limited thereto. For example, the second optical layer 117b may be a diffusion layer, a diffusion layer window, a window diffusion layer, or the like. However, the embodiments of the present disclosure are not limited thereto.

The second optical layer 117b may be made of an organic insulating material. However, the embodiments of the present disclosure are not limited thereto. The second optical layer 117b may be made of the same material as the first optical layer 117a. However, the embodiments of the present disclosure are not limited thereto. For example, the first optical layer 117a may include fine particles, and the second optical layer 117b may include no fine particle. For example, the second optical layer 117b may be made of siloxane. However, the embodiments of the present disclosure are not limited thereto.

For example, a thickness of the first optical layer 117a may be smaller than a thickness of the second optical layer 117b. However, the embodiments of the present disclosure are not limited thereto. Therefore, when viewed in a plan view, an area, in which the first optical layer 117a is disposed, may include a concave portion recessed inward from a top surface of the second optical layer 117b.

According to the present disclosure, the second electrode CE2 may be disposed on the first optical layer 117a and the second optical layer 117b. For example, the second electrode CE2 may be electrically connected to the plurality of contact electrodes CCE through the contact hole of the second optical layer 117b. For example, the second electrode CE2 may be disposed on the plurality of micro-LEDs ED. For example, the second electrode CE2 may include a transparent conductive oxide made of indium tin oxide (ITO), indium zinc oxide (IZO), or the like. However, the embodiments of the present disclosure are not limited thereto. For example, the second electrode CE2 may be disposed to be in contact with the cathode electrode 135. For example, the second electrode CE2 may overlap the first optical layer 117a. For example, the second electrode CE2 may cover an outer flat surface of the first optical layer 117a.

The second electrode CE2 may continuously extend in the first direction X of the substrate 110. Therefore, the second electrode CE2 may be connected in common to the plurality of pixels PX arranged in the first direction X of the substrate 110. For example, the second electrode CE2 may be connected in common to the plurality of pixels PX.

According to the present disclosure, the second electrode CE2 may continuously extend on the first optical layer 117a, the second optical layer 117b, and the micro-LED ED. The area, in which the first optical layer 117a is disposed, may include the concave portion recessed inward from the top surface of the second optical layer 117b. Therefore, because a first portion of the second electrode CE2 disposed on the first optical layer 117a is disposed along the concave portion, the first portion of the second electrode CE2 may be disposed at a position lower than a second portion of the second electrode CE2 disposed on the second optical layer 117b.

A third optical layer 117c may be disposed on the second electrode CE2. The third optical layer 117c may be disposed to overlap the plurality of micro-LEDs ED and the first optical layer 117a. Because the third optical layer 117c is disposed above the second electrode CE2 and the plurality of micro-LEDs ED, it is possible to suppress a Mura that may occur in some of the plurality of micro-LEDs ED. For example, when the plurality of micro-LEDs ED is transferred onto the substrate 110 of the display device 1000, there may occur an area in which intervals between the plurality of micro-LEDs ED are not uniform because of a process deviation or the like. In case that the intervals between the plurality of micro-LEDs ED are not uniform, light-emitting areas of the plurality of micro-LEDs ED may be disposed non-uniformly, and a user may visually recognize a Mura. Therefore, the third optical layer 117c, which is configured to uniformly diffuse light, is provided above the plurality of micro-LEDs ED, which may reduce a situation in which the light emitted from some of the micro-LEDs ED is visually recognized as a Mura. Therefore, the light emitted from the plurality of micro-LEDs ED may be uniformly diffused by the third optical layer 117c and extracted to the outside of the display device 1000, which may improve the luminance uniformity of the display device 1000.

The third optical layer 117c may be made of an organic insulating material in which fine particles are dispersed. However, the embodiments of the present disclosure are not limited thereto. For example, the third optical layer 117c may be made of siloxane in which fine metal particles such as titanium dioxide (TiO2) particles are dispersed. However, the embodiments of the present disclosure are not limited thereto. For example, the third optical layer 117c may be made of the same material as the first optical layer 117a. However, the embodiments of the present disclosure are not limited thereto. For example, the third optical layer 117c may be a diffusion layer or a top diffusion layer. However, the embodiments of the present disclosure are not limited thereto.

According to the present disclosure, the light emitted from the plurality of micro-LEDs ED may be scattered by the fine particles dispersed in the third optical layer 117c, and the light may be discharged to the outside of the display device 1000. The third optical layer 117c may uniformly mix the light beams emitted from the plurality of micro-LEDs ED, which may further improve the luminance uniformity of the display device 1000. Further, the light extraction efficiency of the display device 1000 may be improved by the light scattered by the plurality of fine particles, such that the display device 1000 may operate with low power consumption.

The black matrix BM may be disposed on the second electrode CE2, the first optical layer 117a, the second optical layer 117b, and the third optical layer 117c in the display area AA. For example, the contact hole of the second optical layer 117b may be filled with the black matrix BM. Because the black matrix BM is configured to cover the display area AA, it is possible to reduce a color mixture and external light reflection of the light emitted from the plurality of subpixels. For example, the black matrix BM is disposed even in the contact hole through which the second electrode CE2 and the contact electrode CCE are connected, which may suppress a leak of light between the plurality of adjacent subpixels.

For example, the black matrix BM may be made of an opaque material. However, the embodiments of the present disclosure are not limited thereto. For example, the black matrix BM may be made of an organic insulating material to which a black pigment or a black dye is added. However, the embodiments of the present disclosure are not limited thereto.

A cover layer 118 may be disposed on the black matrix BM in the display area AA. The cover layer 118 may protect components disposed below the cover layer 118. For example, the cover layer 118 may be made of an organic insulating material. However, the embodiments of the present disclosure are not limited thereto. For example, the cover layer 118 may be made of photoresist, polyimide (PI), or a photo acrylic material. However, the embodiments of the present disclosure are not limited thereto. For example, the cover layer 118 may be an overcoating layer, an insulation layer, or the like. However, the embodiments of the present disclosure are not limited thereto.

The polarizing layer 293 may be disposed on the cover layer 118 by means of a first bonding layer 291. The cover member 200 may be disposed on the polarizing layer 293 by means of a second bonding layer 295. For example, the first bonding layer 291 and the second bonding layer 295 may each include an optically clear adhesive (OCA), an optically clear resin (OCR), a pressure-sensitive adhesive (PSA), or the like. However, the embodiments of the present disclosure are not limited thereto.

According to the present disclosure, the plurality of pad electrodes PE may be disposed on the third insulation layer 115c in the second non-display area NA2. For example, the plurality of pad electrodes PE may be at least partially exposed from the passivation layer 116. For example, the plurality of pad electrodes PE may be electrically connected to the second-fourth connection line 122d through the contact hole of the third insulation layer 115c.

A bonding layer ACF may be disposed on the plurality of pad electrodes PE. The bonding layer ACF may be a bonding layer made by dispersing conductive balls in an insulating material. However, the embodiments of the present disclosure are not limited thereto. In case that heat or pressure is applied to the bonding layer ACF, the conductive balls are electrically connected in a portion to which heat or pressure is applied, such that the bonding layer ACF may have conductive properties. The bonding layer ACF may be disposed between the plurality of pad electrodes PE and the flexible circuit board (or flexible film) 400 and attach or bond the flexible circuit board (or flexible film) 400 to the plurality of pad electrodes PE. For example, the bonding layer ACF may be an anisotropic conductive film (ACF). However, the embodiments of the present disclosure are not limited thereto.

The flexible circuit board (or flexible film) 400 may be disposed on the bonding layer ACF. The flexible circuit board (or flexible film) 400 may be electrically connected to the plurality of pad electrodes PE through the bonding layer ACF. Therefore, the signals outputted from the flexible circuit board (or flexible film) 400 and the printed circuit board 500 may be transmitted to the pixel drive circuit PD in the display area AA through the plurality of pad electrodes PE, the second-fourth connection line 122d, the second-third connection line 122c, the second-second connection line 122b, and the second-first connection line 122a.

With reference to FIG. 10, at least one sensor ALS is disposed below the display panel 100 in an area corresponding to at least one hole 510. At least one sensor ALS may include a temperature detection sensor configured to detect a change in temperatures of the surroundings or a light detection sensor configured to detect a change in amount of external light.

At least one sensor ALS may be disposed in the area corresponding to at least one hole 510 and detect a change in light amount or temperature of the outside of the display device 1000.

For example, in case that at least one sensor is the light detection sensor, the light detection sensor may detect a change in amount of light entering from the outside through at least one hole 510.

For example, the sensor ALS may overlap at least some of the plurality of pixels PX. In addition, in at least some of the pixels PX that overlap the sensor ALS, the sensor ALS may overlap at least a part of the first transmission hole BMO1 in the first area PXA1. Alternatively, all the first transmission holes BMO1 of at least some of the pixels PX, which overlap the sensor ALS, may overlap the sensor ALS.

The first transmission holes BMO1, which are disposed in some of the other pixels PX that do not overlap the sensor ALS, may include the first transmission holes BMO1 identical in shapes and areas in a plan view to the first transmission holes BMO1 disposed in at least some of the pixels PX that overlap the sensor ALS. For example, the first transmission holes BMO1, which overlap the sensor ALS in at least some of the pixels PX that overlap the sensor ALS, may be identical in number, shape in a plan view, and area in a plan view to the first transmission holes BMO1 of some of the other pixels PX that do not overlap the sensor ALS. For example, in at least some of the pixels PX that overlap the sensor ALS, the first transmission hole BMO1, which is identical to the first transmission hole BMO1 that overlaps the sensor ALS, may also be disposed, in the same way, in another pixel PX that does not overlap the sensor ALS.

In case that the plurality of micro-LEDs are disposed in one subpixel, the black matrix may be disposed in the remaining area excluding one micro-LED that is finally used. However, when the black matrix is disposed as described above, it may be difficult to ensure a sufficient transmittance rate of the display panel. For this reason, it may be difficult for a sensor, which is disposed on a lower portion of the display panel, to detect a change in external environment, e.g., a change in outside temperature, humidity, light amount, or the like.

For example, the black matrix may block the light entering from the outside. Therefore, the light detection sensor, which may be disposed on the lower portion of the display panel, may not detect a change in amount of external light. When the light detection sensor cannot properly detect the light entering from the outside as described above, the external environment may not be properly recognized. Therefore, it is impossible to adjust the light amount of the display panel in accordance with the external environment.

Therefore, in the display device 1000 according to the embodiment of the present disclosure, the plurality of pixels PX each include the black matrix BM on which the first transmission hole BMO1, which does not overlap (e.g., non-overlapping) each of the plurality of micro-LEDs ED, is disposed. That is, in the display device 1000 according to the embodiment of the present disclosure, the black matrix BM further includes the one or more first transmission holes BMO1 in the area excluding the second transmission holes BMO2 that overlap the plurality of micro-LEDs ED. The first transmission hole BMO1 disposed in the black matrix BM may transmit external environmental elements, such as the light amount, to the lower portion of the display panel. Therefore, the external environmental elements reach the sensor ALS disposed on the lower portion of the display panel 100, such that the sensor ALS may detect the change in external environment.

For example, the first transmission hole BMO1 may transmit the light entering from the outside. Therefore, the sensor ALS disposed on the lower portion of the display panel 100 may detect the change in amount of light entering from the outside. Therefore, in the display device 1000 according to the embodiment of the present disclosure, the luminance of the display device 1000 may be adjusted in accordance with the change in external environment. For example, in the display device 1000 according to the embodiment of the present disclosure, the luminance of the display panel 100 may be adjusted to be low in case that the amount of light, which enters from the outside and is detected by the sensor, is large. Alternatively, the luminance of the display panel 100 may be increased in case that the amount of light entering from the outside is small. As described above, the display device 1000 according to the embodiment of the present disclosure may adjust the luminance of the display panel 100 in accordance with the amount of light entering from the outside.

In addition, the display device 1000 according to the embodiment of the present disclosure may operate the high-efficiency display device with low power consumption by adjusting the luminance in accordance with the external environment.

Meanwhile, the transmission hole may be disposed in the black matrix in order to transmit the external environmental element only in the area that overlaps the sensor disposed on the lower portion of the display panel. However, there is a problem in that a partial area of a part of the black matrix, in which the transmission hole is disposed, is visually recognized as a Mura in case that the transmission hole is disposed only in the partial area of black matrix that overlaps the sensor in the display area.

Therefore, according to the embodiment of the present disclosure, the black matrix BM may include at least one first transmission hole BMO1 in all the plurality of pixels PX disposed in the entire display area AA. For example, the black matrix BM may include at least one first transmission hole BMO1 in all the plurality of pixels PX in the area, which overlaps the sensor ALS, and the area that does not overlap the sensor ALS. Therefore, it is possible to inhibit or reduce the black matrix BM from being visually recognized as a Mura.

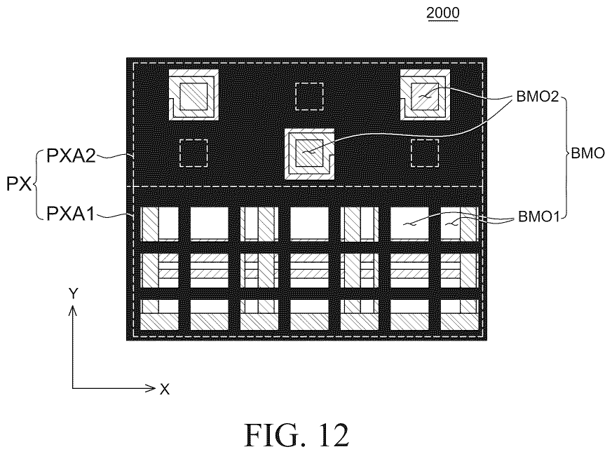

FIG. 12 is a top plan view of a display device according to another embodiment of the present disclosure. For example, FIG. 12 is an enlarged top plan view of one pixel PX in a display device 2000 according to another embodiment of the present disclosure.

The display device 2000 in FIG. 12 is substantially identical in configuration to the display device 1000 in FIGS. 1 to 11, except for a shape of the first transmission hole BMO1. Therefore, a repeated description will be omitted.

With reference to FIG. 12, in the second areas PXA2 of the plurality of pixels PX, the black matrix BM may include the plurality of first transmission holes BMO1.

A shape of each of the plurality of first transmission holes BMO1 in a plan view is a square shape.

All the areas of the plurality of first transmission holes BMO1 in a plan view may be equal to one another. An area of each of the plurality of first transmission holes BMO1 may be smaller than an area of each of the plurality of second transmission holes BMO2. For example, a length of any one first transmission hole BMO1 in the first direction X may be shorter than a length of any one second transmission hole BMO2 in the first direction X. Further, a length of any one first transmission hole BMO1 in the second direction Y may be shorter than a length of any one second transmission hole BMO2 in the second direction Y.

In the plurality of pixels PX, an overall area of the plurality of first transmission holes BMO1 in a plan view may be smaller than an overall area of the first area PXA1.

The plurality of first transmission holes BMO1 may be disposed to be spaced apart from one another in the first direction X. For example, the plurality of first transmission holes BMO1 may be disposed in a plurality of columns. In this case, the plurality of first transmission holes BMO1 may be spaced apart from one another at equal intervals in the first direction X. Alternatively, the plurality of first transmission holes BMO1 may be disposed at different intervals in the first direction X.

The plurality of first transmission holes BMO1 may be disposed to be spaced apart from one another in the second direction Y. For example, the plurality of first transmission holes BMO1 may be disposed in a plurality of rows. In this case, the plurality of first transmission holes BMO1 may be spaced apart from one another at equal intervals in the second direction Y. Alternatively, the plurality of first transmission holes BMO1 may be disposed at different intervals in the second direction Y.

A distance at which the plurality of first transmission holes BMO1 are spaced apart from one another in the first direction X and a distance at which the plurality of first transmission holes BMO1 are spaced apart from one another in the second direction Y may be equal to each other. Alternatively, the distance at which the plurality of first transmission holes BMO1 are spaced apart from one another in the first direction X and the distance at which the plurality of first transmission holes BMO1 are spaced apart from one another in the second direction Y may be different from each other.

The plurality of first transmission holes BMO1 and the plurality of second transmission holes BMO2 may be disposed to be spaced apart from one another in the second direction Y. Therefore, the black matrix BM may be disposed between the plurality of first transmission holes BMO1 and the plurality of second transmission holes BMO2.

According to another embodiment of the present disclosure, the black matrix BM disposed in the first area PXA1 of each of the plurality of pixels PX may include the plurality of first transmission holes BMO1. Therefore, the external environmental elements, such as the light amount, may reach the sensor ALS disposed on the lower portion of the display panel 100 through the plurality of first transmission holes BMO1. Therefore, the sensor ALS may detect a change in the external environment.

For example, the sensor ALS disposed on the lower portion of the display panel 100 may be the light detection sensor. Therefore, the light detection sensor may detect a change in amount of light entering through the plurality of first transmission holes BMO1. Therefore, the display device 2000 according to another embodiment of the present disclosure may adjust the luminance in accordance with the change in amount of external light.

Meanwhile, in case that the black matrix is not sufficiently disposed between the adjacent pixels, there may occur an interference such as a mixture of light beams emitted from the adjacent pixels.

Therefore, according to another embodiment of the present disclosure, in each of the plurality of pixels PX, an overall area of the first transmission hole BMO1 may be smaller than an area of the first area PXA1. Therefore, when the area of the black matrix BM disposed between the adjacent pixels PX increases, the interference between the light beams emitted from the adjacent pixels PX may be suppressed. In addition, the display device 2000 according to another embodiment of the present disclosure may implement images with higher quality.

According to another embodiment of the present disclosure, the black matrix BM may include at least one first transmission hole BMO1 in all the plurality of pixels PX in the area, which overlaps the sensor ALS, and the area that does not overlap the sensor ALS. Therefore, it is possible to inhibit or reduce the black matrix BM from being visually recognized as a Mura in a partial area of each of the plurality of pixels PX.

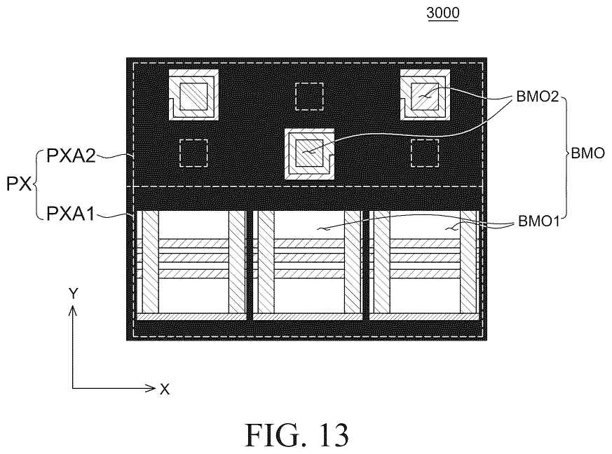

FIG. 13 is a top plan view of a display device according to still another embodiment of the present disclosure. For example, FIG. 13 is an enlarged top plan view of one pixel PX in a display device 3000 according to still another embodiment of the present disclosure.

The display device 3000 in FIG. 13 is substantially identical in configuration to the display device 1000 in FIGS. 1 to 11, except for a shape of the first transmission hole BMO1. Therefore, a repeated description will be omitted.

With reference to FIG. 13, the black matrix BM disposed in the first area PXA1 of each of the plurality of pixels PX may include the plurality of first transmission holes BMO1.

A shape of each of the plurality of first transmission holes BMO1 in a plan view is a square shape. For example, in a plan view, a length of each of the plurality of first transmission holes BMO1 in the first direction X and a length of each of the plurality of first transmission holes BMO1 in the second direction Y may be equal to each other.

In a plan view, an area of each of the plurality of first transmission holes BMO1 may be larger than an area of each of the plurality of second transmission holes BMO2. For example, a length of any one first transmission hole BMO1 in the first direction X may be longer than a length of any one second transmission hole BMO2 in the first direction X. Further, a length of any one first transmission hole BMO1 in the second direction Y may be longer than a length of any one second transmission hole BMO2 in the second direction Y.

All the areas of the plurality of first transmission holes BMO1 in a plan view may be equal to one another. However, the present disclosure is not limited thereto. For example, areas of at least some of the plurality of first transmission holes BMO1 may be different from one another.

In a plan view, an overall area of the plurality of first transmission holes BMO1 may be smaller than an area of the first area PXA1.

The plurality of first transmission holes BMO1 may be disposed to be spaced apart from one another in the first direction X. For example, the plurality of first transmission holes BMO1 may be disposed in a plurality of columns. In this case, distances at which the plurality of first transmission holes BMO1 are spaced apart from one another in the first direction X may be equal to one another. However, the present disclosure is not limited thereto.

The plurality of first transmission holes BMO1 may be disposed in the same row in the first direction X. In the present disclosure, “the same row” may mean that all the points at a center of the length in the second direction Y are disposed on the same line in the first direction X in each of the plurality of first transmission holes BMO1. For example, in case that all the plurality of first transmission holes BMO1 having the same area in a plan view are disposed in the same row, top or bottom surfaces of the plurality of first transmission holes BMO1 may be disposed on the same line. In case that the plurality of first transmission holes BMO1 having different areas in a plan view are disposed in the same row, the top or bottom surfaces of the plurality of first transmission holes BMO1 may be disposed on different straight lines.

The plurality of first transmission holes BMO1 may be disposed in a single row in the first direction X.

The plurality of first transmission holes BMO1 may be spaced apart from the plurality of second transmission holes BMO2 in the second direction Y. Therefore, the black matrix BM may be disposed between the plurality of first transmission holes BMO1 and the plurality of second transmission holes BMO2.

According to still another embodiment of the present disclosure, the external environmental elements, such as the light amount, may reach the sensor ALS disposed on the lower portion of the display panel 100 through the plurality of first transmission holes BMO1. Therefore, the sensor ALS may more precisely detect a change in external environment.

For example, the sensor ALS disposed on the lower portion of the display panel 100 may be the light detection sensor. Therefore, it is possible to detect a change in amount of light entering through the plurality of first transmission holes BMO1. Therefore, the display device 3000 according to still another embodiment of the present disclosure may more precisely adjust the luminance of the display device 3000 in accordance with the change in amount of external light.

Meanwhile, in case that the black matrix is not sufficiently disposed between the adjacent pixels, there may occur an interference such as a mixture of light beams emitted from the adjacent pixels.

Therefore, according to still another embodiment of the present disclosure, in each of the plurality of pixels PX, an overall area of the first transmission hole BMO1 may be smaller than an area of the first area PXA1. Therefore, when the area of the black matrix BM disposed between the adjacent pixels PX further increases, the interference between the light beams emitted from the adjacent pixels PX may be further suppressed. In addition, the display device 3000 according to still another embodiment of the present disclosure may implement images with higher quality.

According to still another embodiment of the present disclosure, the black matrix BM may include at least one first transmission hole BMO1 in all the pixels PX in the area, which overlaps the sensor ALS, and the area that does not overlap the sensor ALS. Therefore, it is possible to inhibit or reduce a part of the black matrix BM from being visually recognized as a Mura.

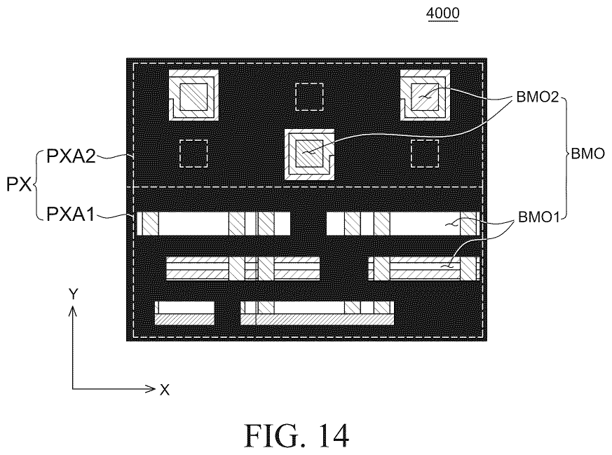

FIG. 14 is a top plan view of a display device according to yet another embodiment of the present disclosure. For example, FIG. 14 is an enlarged top plan view of one pixel PX in a display device 4000 according to yet another embodiment of the present disclosure.

The display device 4000 in FIG. 14 is substantially identical in configuration to the display device 1000 in FIGS. 1 to 11, except for a shape of the first transmission hole BMO1. Therefore, a repeated description will be omitted.

With reference to FIG. 14, the black matrix BM disposed in the first area PXA1 of each of the plurality of pixels PX may include the plurality of first transmission holes BMO1.

A shape of each of the plurality of first transmission holes BMO1 in a plan view may be a rectangular shape. For example, in a plan view, a length of each of the plurality of first transmission holes BMO1 in the first direction X may be longer than a length of each of the plurality of first transmission holes BMO1 in the second direction Y.

The lengths of the plurality of first transmission holes BMO1 in the first direction X may be different from one another. Alternatively, the lengths of at least some of the plurality of first transmission holes BMO1 in the first direction X may be equal to one another. The lengths of the plurality of first transmission holes BMO1 in the second direction Y may be equal to one another. Alternatively, the lengths of at least some of the plurality of first transmission holes BMO1 in the second direction Y may be different from one another.

The areas of all the plurality of first transmission holes BMO1 in a plan view may be different from one another. Alternatively, the areas of at least some of the plurality of first transmission holes BMO1 in a plan view may be equal to one another.

The overall area of the plurality of first transmission holes BMO1 in a plan view may be smaller than the area of the first area PXA1.

The plurality of first transmission holes BMO1 may be disposed to be spaced apart from one another in the first direction X.

In the same row, the distances at which the plurality of first transmission holes BMO1 are spaced apart from one another in the first direction X may be equal to or different from one another. For example, the plurality of first transmission holes BMO1 disposed in any one row may be spaced apart from one another at equal intervals in the first direction X. However, the present disclosure is not limited thereto.

In the different rows, the distances at which the plurality of first transmission holes BMO1 are spaced apart from one another in the first direction X may be equal to or different from one another. A distance at which the plurality of first transmission holes BMO1 disposed in a first row are spaced apart from one another in the first direction X and a distance at which the plurality of first transmission holes BMO1 disposed in a second row are spaced apart from one another in the first direction X may be different from each other. However, the present disclosure is not limited thereto.

The plurality of first transmission holes BMO1 may be disposed to be spaced apart from one another in the second direction Y. In this case, the distances at which the plurality of first transmission holes BMO1 are spaced apart from one another in the second direction Y may be equal to or different from one another. For example, the plurality of first transmission holes BMO1 may be disposed in a plurality of rows in a plan view. However, the present disclosure is not limited thereto. Only one first transmission hole BMO1 may be disposed in at least any one of the plurality of rows.

The plurality of first transmission holes BMO1 and the plurality of second transmission holes BMO2 may be spaced apart from one another in the second direction Y. Therefore, the black matrix BM may be disposed between the plurality of first transmission holes BMO1 and the plurality of second transmission holes BMO2.

According to yet another embodiment of the present disclosure, the external environmental elements, such as the light amount, may reach the sensor ALS disposed on the lower portion of the display panel 100 through the plurality of first transmission holes BMO1. Therefore, the sensor ALS may more precisely detect a change in external environment.

For example, the sensor ALS disposed on the lower portion of the display panel 100 may be the light detection sensor. Therefore, it is possible to more precisely detect a change in amount of light entering through the plurality of first transmission holes BMO1. Therefore, the display device 4000 according to yet another embodiment of the present disclosure may more precisely adjust the luminance of the display device 4000 in accordance with the change in amount of external light.

Meanwhile, in case that the black matrix is not sufficiently disposed between the adjacent pixels, there may occur an interference such as a mixture of light beams emitted from the adjacent pixels.

Therefore, according to yet another embodiment of the present disclosure, in each of the plurality of pixels PX, the overall area of the first transmission hole BMO1 may be smaller than the area of the first area PXA1. Therefore, when the area of the black matrix BM disposed between the adjacent pixels PX increases, the interference between the light beams emitted from the adjacent pixels PX may be further suppressed. In addition, the display device 4000 according to yet another embodiment of the present disclosure may implement images with higher quality.

In addition, according to yet another embodiment of the present disclosure, the black matrix BM may include at least one first transmission hole BMO1 in all the pixels PX in the area, which overlaps the sensor ALS, and the area that does not overlap the sensor ALS. Therefore, it is possible to inhibit or reduce a part of the black matrix BM from being visually recognized as a Mura.

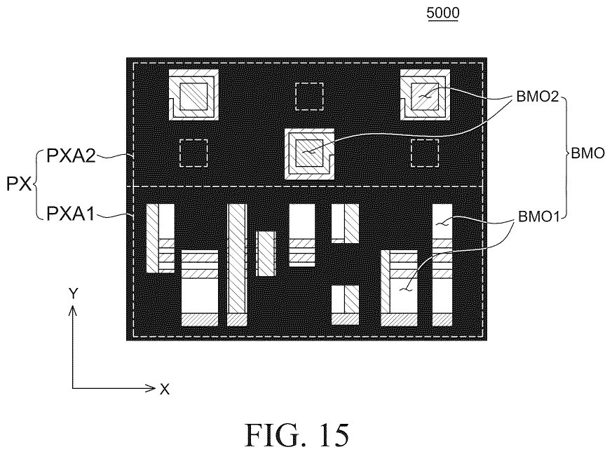

FIG. 15 is a top plan view of a display device according to still yet another embodiment of the present disclosure. For example, FIG. 15 is an enlarged top plan view of one pixel PX in a display device 5000 according to still yet another embodiment of the present disclosure.

The display device 5000 in FIG. 15 is substantially identical in configuration to the display device 1000 in FIGS. 1 to 11, except for a shape of the first transmission hole BMO1. Therefore, a repeated description will be omitted.

With reference to FIG. 15, the black matrix BM disposed in the first area PXA1 of each of the plurality of pixels PX may include the plurality of first transmission holes BMO1.

A shape of each of the plurality of first transmission holes BMO1 in a plan view may be a rectangular shape. For example, in a plan view, a length of each of the plurality of first transmission holes BMO1 in the first direction X may be shorter than a length of each of the plurality of first transmission holes BMO1 in the second direction Y.

The lengths of the plurality of first transmission holes BMO1 in the first direction X may be different from one another. However, the present disclosure is not limited thereto. For example, the lengths of at least some of the plurality of first transmission holes BMO1 in the first direction X may be equal to one another.

The lengths of the plurality of first transmission holes BMO1 in the second direction Y may be different from one another. However, the present disclosure is not limited thereto. For example, the lengths of at least some of the plurality of first transmission holes BMO1 in the second direction Y may be equal to one another.

The areas of the plurality of first transmission holes BMO1 in a plan view may be different from one another. Alternatively, the areas of at least some of the plurality of first transmission holes BMO1 may be equal to one another.

The overall area of the plurality of first transmission holes BMO1 in a plan view may be smaller than the area of the first area PXA1.

The plurality of first transmission holes BMO1 may be disposed to be spaced apart from one another in the first direction X. For example, the plurality of first transmission holes BMO1 may be disposed in a plurality of columns.

One first transmission hole BMO1 may be disposed in each of the plurality of columns. Alternatively, the plurality of first transmission holes BMO1 spaced apart from one another in the second direction Y may be disposed in at least some of the plurality of columns. For example, the plurality of first transmission holes BMO1 may be disposed in the same column. In the present disclosure, “the same column” may mean that all the points at a center of the length in the first direction X are disposed on the same line in the second direction Y in each of the plurality of first transmission holes BMO1.

The distances at which the plurality of first transmission holes BMO1 are spaced apart from one another in the first direction X may be equal to or different from one another.

Meanwhile, the plurality of first transmission holes BMO1 spaced apart from one another in the first direction X may not be disposed in the same row. However, the present disclosure is not limited thereto. For example, at least some of the plurality of first transmission holes BMO1 spaced apart from one another in the first direction X may be disposed in the same row.

The plurality of first transmission holes BMO1 may be spaced apart from one another at equal intervals in the first direction X. Alternatively, the plurality of first transmission holes BMO1 may be spaced apart from one another at different intervals in the first direction X.

The plurality of first transmission holes BMO1 may be disposed to be spaced apart from the plurality of second transmission holes BMO2 in the second direction Y. Therefore, the black matrix BM may be disposed between the plurality of first transmission holes BMO1 and the plurality of second transmission holes BMO2.

According to still yet another embodiment of the present disclosure, the external environmental elements, such as the light amount, may reach the sensor ALS disposed on the lower portion of the display panel 100 through the plurality of first transmission holes BMO1. Therefore, the sensor ALS may more precisely detect a change in external environment.

For example, the sensor ALS disposed on the lower portion of the display panel 100 may be the light detection sensor. Therefore, it is possible to more precisely detect a change in amount of light entering through the plurality of first transmission holes BMO1. Therefore, the display device 5000 according to still yet another embodiment of the present disclosure may precisely adjust the luminance of the display device 5000 in accordance with the change in amount of external light.

Meanwhile, in case that the black matrix is not sufficiently disposed between the adjacent pixels, there may occur an interference such as a mixture of light beams emitted from the adjacent pixels.

Therefore, according to still yet another embodiment of the present disclosure, in each of the plurality of pixels PX, the overall area of the first transmission hole BMO1 may be smaller than the area of the first area PXA1. Therefore, when the area of the black matrix BM disposed between the adjacent pixels PX increases, the interference between the light beams emitted from the adjacent pixels PX may be further suppressed. In addition, the display device 5000 according to still yet another embodiment of the present disclosure may implement images with higher quality.

According to still yet another embodiment of the present disclosure, the black matrix BM may include at least one first transmission hole BMO1 in all the pixels PX in the area, which overlaps the sensor ALS, and the area that does not overlap the sensor ALS. Therefore, it is possible to inhibit or reduce a part of the black matrix BM from being visually recognized as a Mura.

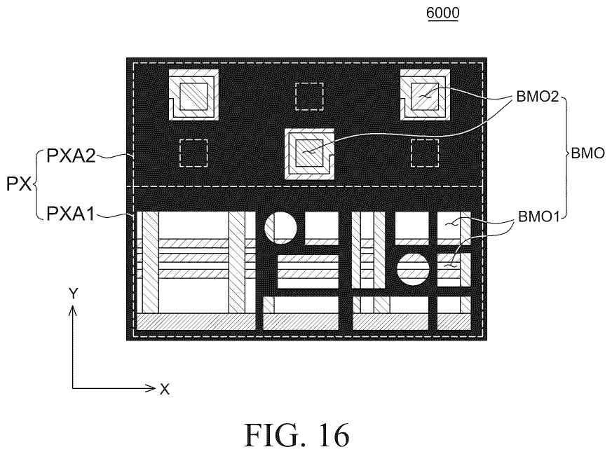

FIG. 16 is a top plan view of a display device according to a further embodiment of the present disclosure. For example, FIG. 16 is an enlarged top plan view of one pixel PX in a display device 6000 according to a further embodiment of the present disclosure.

The display device 6000 in FIG. 16 is substantially identical in configuration to the display device 1000 in FIGS. 1 to 11, except for a shape of the first transmission hole BMO1. Therefore, a repeated description will be omitted.

With reference to FIG. 16, the black matrix BM disposed in the first area PXA1 of each of the plurality of pixels PX may include the plurality of first transmission holes BMO1.

The shapes of the plurality of first transmission holes BMO1 in a plan view may include various first transmission holes BMO1. For example, the plurality of first transmission holes BMO1 may include at least two or more of the plurality of first transmission holes BMO1, which have square shapes in a plan view, the plurality of first transmission holes BMO1, which have rectangular shapes, and the plurality of first transmission holes BMO1 that have circular shapes. In this case, at least some of the plurality of first transmission holes BMO1, which have rectangular shapes in a plan view, may be formed such that the length in the first direction X is longer than the length in the second direction Y. Further, some of the other first transmission holes BMO1, which have rectangular shapes in a plan view, may be formed such that the length in the first direction X is shorter than the length in the second direction Y.

In the plurality of first transmission holes BMO1 having the same shape in a plan view, the areas of the plurality of first transmission holes BMO1 may be different from one another. Alternatively, the areas of at least some of the plurality of first transmission holes BMO1 in a plan view may be equal to one another.

For example, in a plan view, the areas of at least some of the plurality of first transmission holes BMO1 having square shapes may be different from one another. In addition, in a plan view, the areas of at least some of the plurality of first transmission holes BMO1 having rectangular shapes may be different from one another. In addition, in a plan view, the areas of at least some of the plurality of first transmission holes BMO1 having circular shapes may be different from one another.

The plurality of first transmission holes BMO1 may be disposed to be spaced apart from one another in the first direction X. For example, the plurality of first transmission holes BMO1 may be disposed in a plurality of columns. The distances at which the plurality of first transmission holes BMO1 are spaced apart from one another in the first direction X may be different from one another. Alternatively, at least some of the plurality of first transmission holes BMO1 may be spaced apart from one another at equal intervals in the first direction X.

The plurality of first transmission holes BMO1 may be disposed to be spaced apart from one another in the second direction Y. For example, the plurality of first transmission holes BMO1 may be disposed in a plurality of rows. The distances at which the plurality of first transmission holes BMO1 are spaced apart from one another in the second direction Y may be different from one another. Alternatively, at least some of the plurality of first transmission holes BMO1 may be spaced apart from one another at equal intervals in the second direction Y.

The plurality of first transmission holes BMO1 having various shapes may be disposed in the same row or the same column. For example, the first transmission hole BMO1, which has a square shape in a plan view, the first transmission hole BMO1, which has a rectangular shape, and the first transmission hole BMO1, which has a circular shape, may be disposed in the same row or the same column. However, the present disclosure is not limited thereto. In another example, only the plurality of first transmission holes BMO1 having the same shape in a plan view may be disposed in the same row or the same column.

Alternatively, only one first transmission hole BMO1 may be disposed in one row or one column. However, the present disclosure is not limited thereto.

The plurality of first transmission holes BMO1 may be randomly disposed in the first area PXA1. For example, the plurality of first transmission holes BMO1 may be disposed in the first area PXA1 without particular regularity.

The plurality of first transmission holes BMO1 and the plurality of second transmission holes BMO2 may be spaced apart from one another in the second direction Y. Therefore, the black matrix BM may be disposed between the plurality of the first transmission holes BMO1 and the second transmission holes BMO2.

In each of the plurality of pixels PX, the overall area of the plurality of first transmission holes BMO1 in a plan view may be smaller than the area of the first area PXA1.

According to the further embodiment of the present disclosure, the external environmental elements, such as the light amount, may reach the sensor ALS disposed on the lower portion of the display panel 100 through the plurality of first transmission holes BMO1. Therefore, the sensor ALS may more precisely detect a change in external environment.

For example, the sensor ALS disposed on the lower portion of the display panel 100 may be the light detection sensor. Therefore, it is possible to more precisely detect a change in amount of light entering through the plurality of first transmission holes BMO1. Therefore, the display device 6000 according to the further embodiment of the present disclosure may precisely adjust the luminance of the display device 6000 in accordance with the change in amount of external light.

Meanwhile, in case that the black matrix is not sufficiently disposed between the adjacent pixels, there may occur an interference such as a mixture of light beams emitted from the adjacent pixels.

Therefore, according to the further embodiment of the present disclosure, in each of the plurality of pixels PX, the overall area of the first transmission hole BMO1 may be smaller than the area of the first area PXA1. Therefore, when the area of the black matrix BM disposed between the adjacent pixels PX increases, the interference between the light beams emitted from the adjacent pixels PX may be further suppressed. In addition, the display device 6000 according to the further embodiment of the present disclosure may implement images with higher quality.

According to the further embodiment of the present disclosure, the black matrix BM may include at least one first transmission hole BMO1 in all the pixels PX in the area, which overlaps the sensor ALS, and the area that does not overlap the sensor ALS. Therefore, it is possible to inhibit or reduce a part of the black matrix BM from being visually recognized as a Mura.

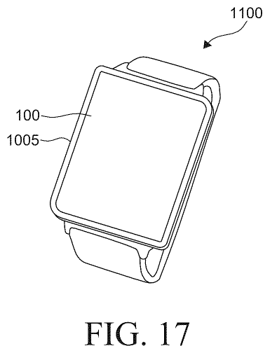

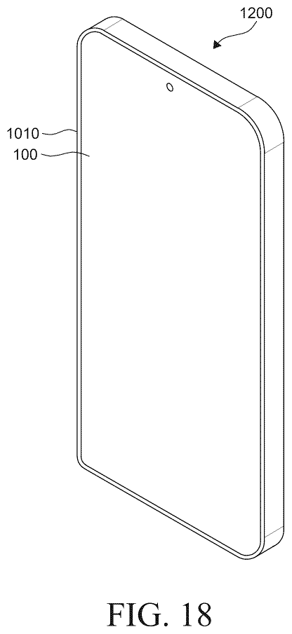

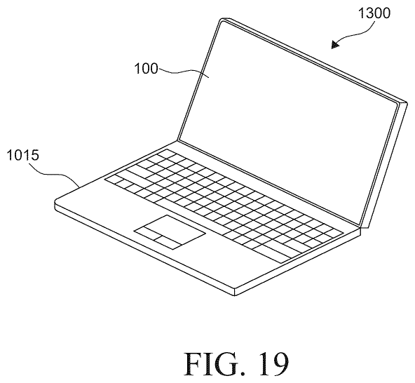

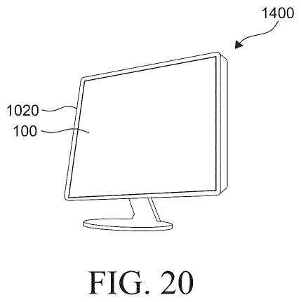

FIGS. 17 to 20 are views illustrating devices to which the display device according to the embodiments of the present disclosure are applied.

With reference to FIGS. 17 to 20, the display device 1000 according to the embodiments of the present disclosure may be included in various devices or electronic devices. For example, with reference to FIGS. 17 to 20, various electronic devices may include a wearable device 1100, a mobile device 1200, a notebook computer 1300, and a monitor or TV 1400. However, the embodiments of the present disclosure are not limited thereto.

The wearable device 1100, the mobile device 1200, the notebook computer 1300, and the monitor or TV 1400 may each respectively include a casing part 1005, 1010, 1015, or 1020, and the display panel 100 or the display device 1000 according to the embodiments of the present disclosure described with reference to FIGS. 1 to 16.

For example, the display device according to the embodiment of the present disclosure may be applied to a mobile device, an image telephone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical instrument, a desktop PC, a laptop PC, a netbook computer, a workstation, a navigation system, a display device for a vehicle, a display device for a theater, a television, a wallpaper device, a signage device, a gaming device, a notebook, a monitor, a camera, a camcorder, a household electrical appliance, and the like.

The exemplary embodiments of the present disclosure can also be described as follows:

A display device according to an aspect of the present disclosure comprises a sensor, a substrate disposed on the sensor and having a display area comprising a plurality of pixels, and a non-display area, a plurality of pixel drive circuits disposed on the substrate, a plurality of banks disposed on the plurality of pixel drive circuits, a plurality of micro-LEDs disposed on the plurality of banks and electrically connected to the plurality of pixel drive circuits, and a black matrix disposed on the plurality of micro-LEDs, wherein the plurality of pixels each comprise: a first area that does not overlap the plurality of micro-LEDs, and a second area excluding the first area, and wherein the black matrix in the first area comprises one or more first transmission holes.

The sensor may comprise a light detection sensor.

The first area may be disposed between the second areas of the plurality of pixels adjacent to one another in the second direction among the plurality of pixels.

A shape of the one or more first transmission holes in a plan view may be any one of a square shape, a rectangular shape, and a circular shape.

The one or more first transmission holes may be provided as a plurality of first transmission holes, wherein a length of each of the plurality of first transmission holes in a first direction may be longer than a length of each of the plurality of first transmission holes in a second direction, and wherein the plurality of first transmission holes may be disposed to be spaced apart from one another in the first or second direction.

The one or more first transmission holes may be provided as a plurality of first transmission holes, wherein a length of each of the plurality of first transmission holes in a first direction may be shorter than a length of each of the plurality of first transmission holes in a second direction, and wherein the plurality of first transmission holes may be disposed to be spaced apart from one another in the first or second direction.

The first transmission hole may be provided as one first transmission hole, and wherein an area of the first transmission hole in a plan view may be equal to an area of the first area.

The black matrix in the second area may further comprise a plurality of second transmission holes that expose some of the plurality of micro-LEDs.

An area of each of the one or more first transmission holes in a plan view may be smaller than an area of each of the plurality of second transmission holes.

A shape of the one or more first transmission holes in a plan view may be a square shape, and wherein the plurality of first transmission holes may be spaced apart from one another at predetermined intervals in first and second directions.

An area of each of the one or more first transmission holes in a plan view may be larger than an area of each of the plurality of second transmission holes.

A shape of each of the plurality of first transmission holes in a plan view may be a square shape, and wherein the plurality of first transmission holes may be disposed in the same row.

The one or more first transmission holes may be provided as a plurality of first transmission holes, and wherein the plurality of first transmission holes may be disposed randomly.

The plurality of micro-LEDs may each comprise an anode electrode, a first semiconductor layer disposed on the anode electrode, an active layer disposed on the first semiconductor layer, a second semiconductor layer disposed on the active layer, and a cathode electrode disposed on the second semiconductor layer.

The display device may further comprise a first electrode disposed below the plurality of micro-LEDs and configured to electrically connect the pixel drive circuit and the anode electrode of each of the plurality of micro-LEDs, and a solder pattern disposed between the first electrode and the anode electrode, wherein the first electrode and the anode electrode are electrically connected by eutectic bonding using the solder pattern.

The sensor may overlap at least a part of the first transmission hole in at least some of the plurality of pixels.

In the plurality of pixels other than at least some pixels that may overlap the sensor, the first transmission holes may comprise the first transmission hole having the same shape and the same area as the first transmission hole that may overlaps the sensor.

A display device according to an another aspect of the present disclosure comprise a sensor, a substrate disposed on the sensor and having a display area comprising a plurality of pixels, and a non-display area, a plurality of pixel drive circuits disposed on the substrate, a plurality of banks disposed on the plurality of pixel drive circuits, a plurality of micro-LEDs disposed on the plurality of banks and electrically connected to the plurality of pixel drive circuits, and a black matrix disposed on the plurality of micro-LEDs, wherein the black matrix comprises, one or more first transmission holes that do not overlap the plurality of micro-LEDs in each of the plurality of pixels, and a plurality of second transmission holes that overlap at least some of the plurality of micro-LEDs.

A shape of each of the one or more first transmission holes in a plan view may be a square shape, a rectangular shape, or a circular shape.

A shape of the one or more first transmission holes in a plan view may be a square shape, wherein the one or more first transmission holes may be provided as a plurality of first transmission holes, wherein an area of each of the plurality of first transmission holes may be smaller than an area of each of the plurality of second transmission holes, and wherein the plurality of first transmission holes may be disposed in a plurality of rows and a plurality of columns.

A shape of the one or more first transmission holes in a plan view may be a square shape, wherein the one or more first transmission holes may be provided as a plurality of first transmission holes, wherein an area of each of the plurality of first transmission holes may be larger than an area of each of the plurality of second transmission holes, and wherein the plurality of first transmission holes may be disposed in the same row.

The black matrix may comprise a first area comprising the first transmission hole, and a second area comprising the second transmission hole, wherein a shape of the one or more first transmission holes in a plan view may be a rectangular shape, wherein the one or more first transmission holes may be provided as one first transmission hole, and wherein the one first transmission hole may completely overlap the first area.

A shape of the one or more first transmission holes in a plan view may be a rectangular shape, wherein the one or more first transmission holes may be provided as a plurality of first transmission holes, and wherein the plurality of first transmission holes may be disposed in a plurality of rows or a plurality of columns.

The one or more first transmission holes may be provided as a plurality of first transmission holes, wherein the plurality of first transmission holes may comprise at least two or more of the plurality of first transmission holes that have square shapes, rectangular shapes, and circular shapes in a plan view, and wherein the plurality of first transmission holes may be disposed randomly.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device comprising:
a sensor;
a substrate on the sensor, the substrate having a display area comprising a plurality of pixels and a non-display area;
a plurality of pixel drive circuits on the substrate;
a plurality of banks on the plurality of pixel drive circuits;
a plurality of micro-light emitting diodes (LEDs) on the plurality of banks, the plurality of micro-LEDs electrically connected to the plurality of pixel drive circuits; and
a black matrix on the plurality of micro-LEDs,
wherein the plurality of pixels each comprise:
a first area that is non-overlapping with the plurality of micro-LEDs; and
a second area excluding the first area, and
wherein the black matrix in the first area comprises one or more first transmission holes.

2. The display device of claim 1, wherein the sensor comprises a light detection sensor.

3. The display device of claim 1, wherein the first area is between second areas of the plurality of pixels adjacent to one another in a second direction.

4. The display device of claim 1, wherein a shape of the one or more first transmission holes in a plan view is any one of a square shape, a rectangular shape, or a circular shape.

5. The display device of claim 1, wherein the one or more first transmission holes include a plurality of first transmission holes,
wherein a length of each of the plurality of first transmission holes in a first direction is longer than a length of each of the plurality of first transmission holes in a second direction, and
wherein the plurality of first transmission holes are spaced apart from one another in the first direction or the second direction.

6. The display device of claim 1, wherein the one or more first transmission holes include a plurality of first transmission holes,
wherein a length of each of the plurality of first transmission holes in a first direction is shorter than a length of each of the plurality of first transmission holes in a second direction, and
wherein the plurality of first transmission holes are spaced apart from one another in the first direction or the second direction.

7. The display device of claim 1, wherein the one or more first transmission holes include one first transmission hole and an area of the one first transmission hole in a plan view is equal to an area of the first area.

8. The display device of claim 1, wherein the black matrix in the second area further comprises a plurality of second transmission holes that expose some of the plurality of micro-LEDs.

9. The display device of claim 8, wherein an area of each of the one or more first transmission holes in a plan view is smaller than an area of each of the plurality of second transmission holes.

10. The display device of claim 9, wherein a shape of the one or more first transmission holes in the plan view is a square shape and the one or more first transmission holes are spaced apart from one another at predetermined intervals in a first direction and a second direction.

11. The display device of claim 8, wherein an area of each of the one or more first transmission holes in a plan view is larger than an area of each of the plurality of second transmission holes.

12. The display device of claim 11, wherein a shape of each of the one or more first transmission holes in the plan view is a square shape and the one or more first transmission holes are disposed in a same row.

13. The display device of claim 1, wherein the one or more first transmission holes include a plurality of first transmission holes and the plurality of first transmission holes are randomly disposed.

14. The display device of claim 1, wherein each of the plurality of micro-LEDs comprises:
an anode electrode;
a first semiconductor layer on the anode electrode;
an active layer on the first semiconductor layer;
a second semiconductor layer on the active layer; and
a cathode electrode on the second semiconductor layer.

15. The display device of claim 14, further comprising:
a first electrode below the plurality of micro-LEDs, the first electrode electrically connecting the pixel drive circuit and the anode electrode of each of the plurality of micro-LEDs; and
a solder pattern between the first electrode and the anode electrode,
wherein the first electrode and the anode electrode are electrically connected using the solder pattern.

16. The display device of claim 1, wherein the sensor overlaps at least a part of the one or more first transmission holes in at least some of the plurality of pixels.

17. The display device of claim 16, wherein in the plurality of pixels other than the at least some of the plurality of pixels that overlap the sensor, the one or more first transmission holes comprise a first transmission hole having a same shape and a same area as a first transmission hole that overlaps the sensor.

18. A display device comprising:
a sensor;
a substrate on the sensor, the substrate having a display area comprising a plurality of pixels and a non-display area;
a plurality of pixel drive circuits on the substrate;
a plurality of banks on the plurality of pixel drive circuits;
a plurality of micro-light emitting diodes (LEDs) on the plurality of banks, the plurality of micro-LEDs electrically connected to the plurality of pixel drive circuits; and
a black matrix on the plurality of micro-LEDs, the black matrix comprising:
one or more first transmission holes that are non-overlapping with the plurality of micro-LEDs in each of the plurality of pixels; and
a plurality of second transmission holes that overlap at least some of the plurality of micro-LEDs.

19. The display device of claim 18, wherein a shape of each of the one or more first transmission holes in a plan view is a square shape, a rectangular shape, or a circular shape.

20. The display device of claim 19, wherein a shape of the one or more first transmission holes in the plan view is a square shape,
wherein the one or more first transmission holes include a plurality of first transmission holes,
wherein an area of each of the plurality of first transmission holes is smaller than an area of each of the plurality of second transmission holes, and
wherein the plurality of first transmission holes are disposed in a plurality of rows and a plurality of columns.

21. The display device of claim 19, wherein a shape of the one or more first transmission holes in the plan view is a square shape,
wherein the one or more first transmission holes include a plurality of first transmission holes,
wherein an area of each of the plurality of first transmission holes is larger than an area of each of the plurality of second transmission holes, and
wherein the plurality of first transmission holes are disposed in a same row.

22. The display device of claim 19, wherein the black matrix comprises:
a first area comprising the one or more first transmission holes; and
a second area comprising the plurality of second transmission holes,
wherein a shape of the one or more first transmission holes in the plan view is a rectangular shape,
wherein the one or more first transmission holes include one first transmission hole, and
wherein the one first transmission hole completely overlaps the first area.

23. The display device of claim 19, wherein a shape of the one or more first transmission holes in the plan view is a rectangular shape,
wherein the one or more first transmission holes include a plurality of first transmission holes, and
wherein the plurality of first transmission holes are disposed in a plurality of rows or a plurality of columns.

24. The display device of claim 19, wherein the one or more first transmission holes include a plurality of first transmission holes and the plurality of first transmission holes are randomly disposed.

25. The display device of claim 24, wherein the plurality of first transmission holes comprise at least two or more of the plurality of first transmission holes that have square shapes, rectangular shapes, or circular shapes in the plan view, respectively.
